(19) United States
(12) Patent Application Publication
(10) Pub. No.: US 2025/0211262 A1
(43) Pub. Date: Jun. 26, 2025

(54) CROSS ROUTE BASED CONFIGURABLE LOCAL OSCILLATOR GENERATION CIRCUIT

(71) Applicant: QUALCOMM Incorporated, San Diego, CA (US)

(72) Inventors: Yunliang Zhu, San Diego, CA (US); Dongling Pan, San Diego, CA (US); Kyle David Holland, San Diego, CA (US); Yiwu Tang, San Diego, CA (US)

(21) Appl. No.: 18/391,211

(22) Filed: Dec. 20, 2023

(51) Int. Cl. H04B 1/00; H04B 1/04

(52) U.S. Cl. CPC H04B 1/0082; H04B 1/0483

(57) ABSTRACT

This disclosure provides systems, methods, and devices for wireless communications that support configurable local oscillator circuitry. In a first aspect, transceiver system includes one or more receive or transmit chains, and a particular chain thereof includes one or more dividers configured to receive a clock signal. The particular chain also includes local oscillator (LO) cross routing circuitry coupled to the one or more dividers and includes a mixer coupled to the LO cross routing circuitry. The particular chain further includes one or more auxiliary mixers coupled to the LO cross routing circuitry, and the LO cross routing circuitry is configured to selectively couple a particular divider of the one or more dividers to the mixer, to at least one auxiliary mixer of the one or more auxiliary mixers, or any combination thereof. Other aspects and features are also claimed and described.

### TECHNICAL FIELD

Aspects of the present disclosure relate generally to wireless communication systems, and more particularly, to radio frequency (RF) processing circuitry for wireless communication systems. Some features may enable and provide improved communications, including improved operation of RF transceivers, such as configurable local oscillator circuitry.

### INTRODUCTION

Wireless communication networks are widely deployed to provide various communication services such as voice, video, packet data, messaging, broadcast, and the like. These wireless networks may be multiple-access networks capable of supporting multiple users by sharing the available network resources.

A wireless communication network may include several components. These components may include wireless communication devices, such as base stations (or node Bs) that may support communication for a number of user equipments (UEs). A UE may communicate with a base station via downlink and uplink. The downlink (or forward link) refers to the communication link from the base station to the UE, and the uplink (or reverse link) refers to the communication link from the UE to the base station.

A base station may transmit data and control information on a downlink to a UE or may receive data and control information on an uplink from the UE. On the downlink, a transmission from the base station may encounter interference due to transmissions from neighbor base stations or from other wireless radio frequency (RF) transmitters. On the uplink, a transmission from the UE may encounter interference from uplink transmissions of other UEs communicating with the neighbor base stations or from other wireless RF transmitters. This interference may degrade performance on both the downlink and uplink.

As the demand for mobile broadband access continues to increase, the possibilities of interference and congested networks grows with more UEs accessing the long-range wireless communication networks and more short-range wireless systems being deployed in communities. Research and development continue to advance wireless technologies not only to meet the growing demand for mobile broadband access, but to advance and enhance the user experience with mobile communications.

Modern wireless communication networks are sophisticated networks that involve operation on multiple frequencies and multiple frequency ranges. RF signals in different frequencies and ranges may use different components or different configurations of components to support a device operating on these wireless communication networks and maintain high signal integrity and high bandwidth across a range of possible network conditions. The duplication of components and number of supported configurations presents challenges in designing RF systems for the UEs and BSs operating on wireless communication networks.

One such example of duplicated components for different operating configurations, is local oscillator circuits. Local oscillator (LO) circuits and/or components thereof may be duplicated for each transmit or receive chain of the device for different operating configurations. Each LO circuit may have dedicated paths for the different operating and the components of each path may consume power during the different operations. The power consumed by these duplicated components can cause significant power usage on the device in many different operating modes.

### BRIEF SUMMARY OF SOME EXAMPLES

The following summarizes some aspects of the present disclosure to provide a basic understanding of the discussed technology. This summary is not an extensive overview of all contemplated features of the disclosure and is intended neither to identify key or critical elements of all aspects of the disclosure nor to delineate the scope of any or all aspects of the disclosure. Its sole purpose is to present some concepts of one or more aspects of the disclosure in summary form as a prelude to the more detailed description that is presented later.

In some aspects, LO generation circuitry includes LO cross route circuitry to provide additional and flexible pathways for LO circuits to enable configurable routing of synchronization signals to different dividers, mixer buffers, and/or mixers during LO signal generation. The LO cross route circuitry provides flexible configuration and selection of LO components, such as mixer buffers and/or mixers, for different power or gain modes. The LO cross route circuitry and flexible configuration and selection of lower power components may significantly reduce LO power consumption. Specifically, the LO cross route circuitry may reduce power consumption when performing LO operations in a default power mode and/or in low power modes. To illustrate, the LO cross route circuitry may enable regular and low power modes to bypass higher power consuming components, such as a main mixer buffer and/or main mixer, to avoid the corresponding higher power consumption, and to utilize lower power consuming auxiliary components.

In one aspect of the disclosure, a transceiver system includes: one or more receive chains; and one or more transmit chains, wherein a receive chain of the one or more receive chains or a transmit chain of the one or more transmit chains includes: one or more dividers configured to receive a clock signal; local oscillator (LO) cross routing circuitry coupled to the one or more dividers; a mixer coupled to the LO cross routing circuitry; and one or more auxiliary mixers coupled to the LO cross routing circuitry, wherein the LO cross routing circuitry is configured to selectively couple a particular divider of the one or more dividers to the mixer, to at least one auxiliary mixer of the one or more auxiliary mixers, or any combination thereof.

In an additional aspect of the disclosure, a method for wireless communication includes: receiving, at local oscillator (LO) cross routing circuitry, a clock signal from a divider; selectively providing, by the LO cross routing circuitry, the clock signal to one or more of a primary mixer buffer, an auxiliary mixer buffer, or both, wherein the LO cross routing circuitry is configured to selectively couple the divider to the primary mixer buffer, the auxiliary mixer buffer, or both; and processing, by the primary mixer buffer, the auxiliary mixer buffer, or both, the clock signal and providing the processed clock signal to a corresponding mixer.

In another aspect of the disclosure, a transceiver system includes: a first oscillator; a second oscillator; local oscillator (LO) cross routing circuitry coupled to the first and second oscillators; a first mixer coupled to the LO cross routing circuitry; and a second mixer coupled to the LO cross routing circuitry, where the LO cross routing circuitry is configured to selectively couple at least one of the first oscillator or the second oscillator to the first mixer or to the second mixer via a corresponding auxiliary mixer buffer, and where the first oscillator and the first mixer are part of a first transmit or receive chain and the second oscillator and the second mixer are part of a second transmit or receive chain.

In an additional aspect of the disclosure, a method for wireless communication includes: receiving, at local oscillator (LO) cross routing circuitry, a clock signal from an oscillator; selectively providing, by the LO cross routing circuitry, the clock signal to one or more of a primary mixer buffer of a first chain, a first auxiliary mixer buffer of the first chain, a second auxiliary mixer buffer of a second chain, or a combination thereof, wherein the LO cross routing circuitry is configured to selectively couple the oscillator to mixers of multiple chains; and processing, by the primary mixer buffer, the first auxiliary mixer buffer, the second auxiliary mixer buffer of a second chain, or a combination thereof, the clock signal and providing the clock signal to a corresponding mixer.

As used herein, a “radio frequency” signal is a signal having a frequency above baseband, which includes, in an example embodiment of a heterodyne receiver, intermediate frequency signals.

As used herein, an “intermediate frequency” signal is a RF signal that has been downconverted from another RF signal to a frequency that is above baseband, such as in an example embodiment of a heterodyne mmWave transceiver that receives a mmWave RF signal and downconverts the mmWave RF signal to a mmWave IF signal that is further processed, such as through further downconversion, to a lower frequency RF signal or a baseband signal.

The foregoing has outlined rather broadly the features and technical advantages of examples according to the disclosure in order that the detailed description that follows may be better understood. Additional features and advantages will be described hereinafter. The conception and specific examples disclosed may be readily utilized as a basis for modifying or designing other structures for carrying out the same purposes of the present disclosure. Such equivalent constructions do not depart from the scope of the appended claims. Characteristics of the concepts disclosed herein, both their organization and method of operation, together with associated advantages will be better understood from the following description when considered in connection with the accompanying figures. Each of the figures is provided for the purposes of illustration and description, and not as a definition of the limits of the claims.

While aspects and implementations are described in this application by illustration to some examples, those skilled in the art will understand that additional implementations and use cases may come about in many different arrangements and scenarios. Innovations described herein may be implemented across many differing platform types, devices, systems, shapes, sizes, packaging arrangements. For example, aspects and/or uses may come about via integrated chip implementations and other non-module-component based devices (e.g., end-user devices, vehicles, communication devices, computing devices, industrial equipment, retail/purchasing devices, medical devices, artificial intelligence (AI)-enabled devices, etc.). While some examples may or may not be specifically directed to use cases or applications, a wide assortment of applicability of described innovations may occur. Implementations may range in spectrum from chip-level or modular components to non-modular, non-chip-level implementations and further to aggregate, distributed, or original equipment manufacturer (OEM) devices or systems incorporating one or more aspects of the described innovations. In some practical settings, devices incorporating described aspects and features may also necessarily include additional components and features for implementation and practice of claimed and described aspects. For example, transmission and reception of wireless signals necessarily includes a number of components for analog and digital purposes (e.g., hardware components including antenna, radio frequency (RF)-chains, power amplifiers, modulators, buffer, processor(s), interleaver, adders/summers, etc.). It is intended that innovations described herein may be practiced in a wide variety of devices, chip-level components, systems, distributed arrangements, end-user devices, etc. of varying sizes, shapes, and constitution.

### BRIEF DESCRIPTION OF THE DRAWINGS

A further understanding of the nature and advantages of the present disclosure may be realized by reference to the following drawings. In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label.

FIG. 1 is a block diagram illustrating details of an example wireless communication system according to one or more aspects.

FIG. 2 is a block diagram illustrating examples of a base station and a user equipment (UE) according to one or more aspects.

FIG. 3 is a block diagram illustrating a frequency (RF) receiver according to one or more aspects.

FIG. 4 is a block diagram illustrating a wireless transceiver that supports enhanced local oscillator generation operations according to one or more aspects.

FIG. 5 is a diagram illustrating an example of LO cross routing circuitry that supports enhanced local oscillator generation operations according to one or more aspects.

FIG. 6 is a diagram illustrating an example of LO cross routing circuitry that supports enhanced local oscillator generation operations according to one or more aspects.

FIG. 7 is a diagram illustrating an example of LO cross routing circuitry that supports enhanced local oscillator generation operations according to one or more aspects.

FIG. 8 is a diagram illustrating an example of LO cross routing circuitry that supports enhanced local oscillator generation operations according to one or more aspects.

FIG. 9 is a diagram illustrating an example of LO cross routing circuitry that supports enhanced local oscillator generation operations according to one or more aspects.

FIG. 10 is a flow diagram illustrating an example process that supports enhanced local oscillator generation operations according to one or more aspects.

FIG. 11 is a flow diagram illustrating an example process that supports enhanced local oscillator generation operations according to one or more aspects.

FIG. 12 is a block diagram of an example UE that supports enhanced local oscillator generation operations in a wireless radio according to one or more aspects of the disclosure.

FIG. 13 is a block diagram of an example base station that supports enhanced local oscillator generation operations in a wireless radio according to one or more aspects of the disclosure.

Like reference numbers and designations in the various drawings indicate like elements.

### DETAILED DESCRIPTION

The detailed description set forth below, in connection with the appended drawings, is intended as a description of various configurations and is not intended to limit the scope of the disclosure. Rather, the detailed description includes specific details for the purpose of providing a thorough understanding of the inventive subject matter. It will be apparent to those skilled in the art that these specific details are not required in every case and that, in some instances, well-known structures and components are shown in block diagram form for clarity of presentation.

The present disclosure provides systems, apparatus, methods, and computer-readable media that support local oscillation signal generation, including techniques for configurable LO generation circuits. The aspects described herein, involve LO cross route circuitry to provide additional and flexible pathways for LO circuits to enable configurable routing of synchronization signals to different dividers, mixer buffers, and/or mixers. The LO cross route circuitry provides flexible configuration and selection of LO components, such as mixer buffers and/or mixers, for different power modes/gain modes. The LO cross route circuitry and flexible configuration and selection of lower power components may significantly reduce LO power consumption. Specifically, the LO cross route circuitry may reduce power consumption when performing LO operations in a default power mode and/or in low power modes. To illustrate, the LO cross route circuitry may enable regular and low power modes to bypass higher power consuming components, such as a main mixer buffer and/or main mixer, to avoid the corresponding higher power consumption, and to utilize lower power consuming auxiliary components. Additionally, the LO cross route circuitry may still enable usage of a main or primary divider corresponding to the main mixer buffer and/or main mixer in a regular mode and in low power modes to maintain phase alignment.

The LO cross route circuitry may be included in a LO generation circuit or block and correspond to one or more additional routes between components of the LO generation circuit. For example, the LO generation circuit may have circuit paths (e.g., traces and/or switched) referred to as cross routes connecting different input signals to different mixer buffers and/or mixers. In some implementations, the LO generation circuit has cross routes connecting different dividers and mixer buffers together. Additionally, or alternatively, the LO generation circuit has cross routes connecting different oscillators and mixer buffers together.

The LO cross route circuitry described herein may include one or more paths routing signals from different oscillators to different mixer buffers and mixers. The LO cross route circuitry may include one or more traces and optionally one or more switches to provide the additional paths which can route signals across or between conventional paths. The LO cross route circuitry is configurable to drive different mixers with different LO input signals based on power modes or gain modes. In some implementations, the LO cross route circuitry provides a path after frequency reduction, which is from the divider output to different mixers. In other implementations, the LO cross route circuitry provides a path for the synchronization signal to a mixer buffer without passing through a divider. Thus, the LO cross route circuitry may be positioned prior to and independent of a divider, after a divider, or both.

The LO cross route circuitry may occur on chip or across chips. Additionally, the LO cross route circuitry may route oscillator signals (e.g., high and low mode oscillator signals) for a transmit or receive chain (TX/RX chain) to a mixer or mixers of the particular TX/RX chain or to a second mixer or second mixers of a second TX/RX chain.

Particular implementations of the subject matter described in this disclosure may be implemented to realize one or more of the following potential advantages or benefits. In some aspects, the present disclosure provides techniques for configurable LO generation circuits which enable additional operational modes and reduce power operations. Specifically, additional conventional or lower power modes may be achieved without additional hardware by utilizing configurable LO cross routing circuitry. Such reuse of components reduces costs, size, and complexity. In addition, the lower power modes may utilize certain components to maintain alignment, such as a primary or main divider for phase alignment, and may utilize other components (mixer and/or mixer buffers) to reduce power consumption.

In various implementations, the techniques and apparatus may be used for wireless communication networks such as code division multiple access (CDMA) networks, time division multiple access (TDMA) networks, frequency division multiple access (FDMA) networks, orthogonal FDMA (OFDMA) networks, single-carrier FDMA (SC-FDMA) networks, LTE networks, GSM networks, 5th Generation (5G) or new radio (NR) networks (sometimes referred to as “5G NR” networks, systems, or devices), as well as other communications networks. As described herein, the terms “networks” and “systems” may be used interchangeably.

A CDMA network, for example, may implement a radio technology such as universal terrestrial radio access (UTRA), cdma2000, and the like. UTRA includes wideband-CDMA (W-CDMA) and low chip rate (LCR). CDMA2000 covers IS-2000, IS-95, and IS-856 standards.

A TDMA network may, for example implement a radio technology such as Global System for Mobile Communication (GSM). The 3rd Generation Partnership Project (3GPP) defines standards for the GSM EDGE (enhanced data rates for GSM evolution) radio access network (RAN), also denoted as GERAN. GERAN is the radio component of GSM/EDGE, together with the network that joins the base stations (for example, the Ater and Abis interfaces) and the base station controllers (A interfaces, etc.). The radio access network represents a component of a GSM network, through which phone calls and packet data are routed from and to the public switched telephone network (PSTN) and Internet to and from subscriber handsets, also known as user terminals or user equipments (UEs). A mobile phone operator's network may comprise one or more GERANs, which may be coupled with UTRANs in the case of a UMTS/GSM network. Additionally, an operator network may also include one or more LTE networks, or one or more other networks. The various different network types may use different radio access technologies (RATs) and RANs.

An OFDMA network may implement a radio technology such as evolved UTRA (E-UTRA), Institute of Electrical and Electronics Engineers (IEEE) 802.11, IEEE 802.16, IEEE 802.20, flash-OFDM and the like. UTRA, E-UTRA, and GSM are part of universal mobile telecommunication system (UMTS). In particular, long-term evolution (LTE) is a release of UMTS that uses E-UTRA. UTRA, E-UTRA, GSM, UMTS and LTE are described in documents provided from an organization named “3rd Generation Partnership Project” (3GPP), and cdma2000 is described in documents from an organization named “3rd Generation Partnership Project 2” (3GPP2). These various radio technologies and standards are known or are being developed. For example, the 3GPP is a collaboration between groups of telecommunications associations that aims to define a globally applicable third generation (3G) mobile phone specification. 3GPP LTE is a 3GPP project which was aimed at improving UMTS mobile phone standard. The 3GPP may define specifications for the next generation of mobile networks, mobile systems, and mobile devices. The present disclosure may describe certain aspects with reference to LTE, 4G, or 5G NR technologies; however, the description is not intended to be limited to a specific technology or application, and one or more aspects described with reference to one technology may be understood to be applicable to another technology. Additionally, one or more aspects of the present disclosure may be related to shared access to wireless spectrum between networks using different radio access technologies or radio air interfaces.

5G networks contemplate diverse deployments, diverse spectrum, and diverse services and devices that may be implemented using an OFDM-based unified, air interface. To achieve these goals, further enhancements to LTE and LTE-A are considered in addition to development of the new radio technology for 5G NR networks. The 5G NR will be capable of scaling to provide coverage (1) to a massive Internet of things (IoTs) with an ultra-high density (e.g., ˜1 M nodes/km²), ultra-low complexity (e.g., ˜10 s of bits/sec), ultra-low energy (e.g., ˜10+ years of battery life), and deep coverage with the capability to reach challenging locations; (2) including mission-critical control with strong security to safeguard sensitive personal, financial, or classified information, ultra-high reliability (e.g., ˜99.9999% reliability), ultra-low latency (e.g., ˜1 millisecond (ms)), and users with wide ranges of mobility or lack thereof; and (3) with enhanced mobile broadband including extreme high capacity (e.g., ˜10 Tbps/km²), extreme data rates (e.g., multi-Gbps rate, 100+ Mbps user experienced rates), and deep awareness with advanced discovery and optimizations.

Devices, networks, and systems may be configured to communicate via one or more portions of the electromagnetic spectrum. The electromagnetic spectrum is often subdivided, based on frequency or wavelength, into various classes, bands, channels, etc. In 5G NR two initial operating bands have been identified as frequency range designations FR1 (410 MHz-7.125 GHz) and FR2 (24.25 GHz-52.6 GHz). The frequencies between FR1 and FR2 are often referred to as mid-band frequencies. Although a portion of FR1 is greater than 6 GHz, FR1 is often referred to (interchangeably) as a “sub-6 GHz” band in various documents and articles. A similar nomenclature issue sometimes occurs with regard to FR2, which is often referred to (interchangeably) as a “millimeter wave” (mmWave) band in documents and articles, despite being different from the extremely high frequency (EHF) band (30 GHz-300 GHz) which is identified by the International Telecommunications Union (ITU) as a “mm Wave” band.

With the above aspects in mind, unless specifically stated otherwise, it should be understood that the term “sub-6 GHz” or the like if used herein may broadly represent frequencies that may be less than 6 GHz, may be within FR1, or may include mid-band frequencies. Further, unless specifically stated otherwise, it should be understood that the term “mmWave” or the like if used herein may broadly represent frequencies that may include mid-band frequencies, may be within FR2, or may be within the EHF band.

5G NR devices, networks, and systems may be implemented to use optimized OFDM-based waveform features. These features may include scalable numerology and transmission time intervals (TTIs); a common, flexible framework to efficiently multiplex services and features with a dynamic, low-latency time division duplex (TDD) design or frequency division duplex (FDD) design; and advanced wireless technologies, such as massive multiple input, multiple output (MIMO), robust mmWave transmissions, advanced channel coding, and device-centric mobility. Scalability of the numerology in 5G NR, with scaling of subcarrier spacing, may efficiently address operating diverse services across diverse spectrum and diverse deployments. For example, in various outdoor and macro coverage deployments of less than 3 GHz FDD or TDD implementations, subcarrier spacing may occur with 15 kHz, for example over 1, 5, 10, 20 MHz, and the like bandwidth. For other various outdoor and small cell coverage deployments of TDD greater than 3 GHz, subcarrier spacing may occur with 30 kHz over 80/100 MHz bandwidth. For other various indoor wideband implementations, using a TDD over the unlicensed portion of the 5 GHz band, the subcarrier spacing may occur with 60 kHz over a 160 MHz bandwidth. Finally, for various deployments transmitting with mmWave components at a TDD of 28 GHz, subcarrier spacing may occur with 120 kHz over a 500 MHz bandwidth.

The scalable numerology of 5G NR facilitates scalable TTI for diverse latency and quality of service (QOS) requirements. For example, shorter TTI may be used for low latency and high reliability, while longer TTI may be used for higher spectral efficiency. The efficient multiplexing of long and short TTIs to allow transmissions to start on symbol boundaries. 5G NR also contemplates a self-contained integrated subframe design with uplink or downlink scheduling information, data, and acknowledgement in the same subframe. The self-contained integrated subframe supports communications in unlicensed or contention-based shared spectrum, adaptive uplink or downlink that may be flexibly configured on a per-cell basis to dynamically switch between uplink and downlink to meet the current traffic needs.

For clarity, certain aspects of the apparatus and techniques may be described below with reference to example 5G NR implementations or in a 5G-centric way, and 5G terminology may be used as illustrative examples in portions of the description below; however, the description is not intended to be limited to 5G applications.

Moreover, it should be understood that, in operation, wireless communication networks adapted according to the concepts herein may operate with any combination of licensed or unlicensed spectrum depending on loading and availability. Accordingly, it will be apparent to a person having ordinary skill in the art that the systems, apparatus and methods described herein may be applied to other communications systems and applications than the particular examples provided.

While aspects and implementations are described in this application by illustration to some examples, those skilled in the art will understand that additional implementations and use cases may come about in many different arrangements and scenarios. Innovations described herein may be implemented across many differing platform types, devices, systems, shapes, sizes, packaging arrangements. For example, implementations or uses may come about via integrated chip implementations or other non-module-component based devices (e.g., end-user devices, vehicles, communication devices, computing devices, industrial equipment, retail devices or purchasing devices, medical devices, AI-enabled devices, etc.). While some examples may or may not be specifically directed to use cases or applications, a wide assortment of applicability of described innovations may occur. Implementations may range from chip-level or modular components to non-modular, non-chip-level implementations and further to aggregated, distributed, or original equipment manufacturer (OEM) devices or systems incorporating one or more described aspects. In some practical settings, devices incorporating described aspects and features may also necessarily include additional components and features for implementation and practice of claimed and described aspects. It is intended that innovations described herein may be practiced in a wide variety of implementations, including both large devices or small devices, chip-level components, multi-component systems (e.g., radio frequency (RF)-chain, communication interface, processor), distributed arrangements, end-user devices, etc. of varying sizes, shapes, and constitution.

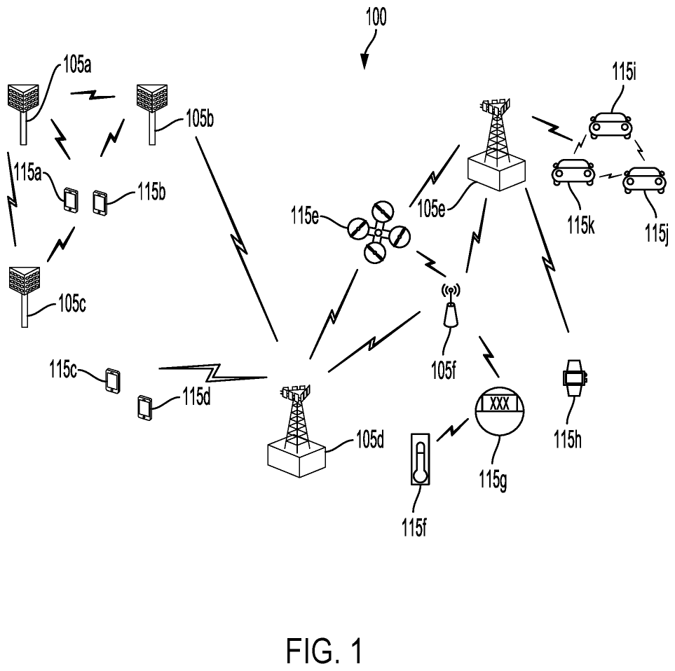

FIG. 1 is a block diagram illustrating details of an example wireless communication system according to one or more aspects. The wireless communication system may include wireless network 100. Wireless network 100 may, for example, include a 5G wireless network. As appreciated by those skilled in the art, components appearing in FIG. 1 are likely to have related counterparts in other network arrangements including, for example, cellular-style network arrangements and non-cellular-style-network arrangements (e.g., device to device or peer to peer or ad hoc network arrangements, etc.).

Wireless network 100 illustrated in FIG. 1 includes a number of base stations 105 and other network entities. A base station may be a station that communicates with the UEs and may also be referred to as an evolved node B (eNB), a next generation eNB (gNB), an access point, and the like. Each base station 105 may provide communication coverage for a particular geographic area. In 3GPP, the term “cell” may refer to this particular geographic coverage area of a base station or a base station subsystem serving the coverage area, depending on the context in which the term is used. In implementations of wireless network 100 herein, base stations 105 may be associated with a same operator or different operators (e.g., wireless network 100 may include a plurality of operator wireless networks). Additionally, in implementations of wireless network 100 herein, base station 105 may provide wireless communications using one or more of the same frequencies (e.g., one or more frequency bands in licensed spectrum, unlicensed spectrum, or a combination thereof) as a neighboring cell. In some examples, an individual base station 105 or UE 115 may be operated by more than one network operating entity. In some other examples, each base station 105 and UE 115 may be operated by a single network operating entity.

A base station may provide communication coverage for a macro cell or a small cell, such as a pico cell or a femto cell, or other types of cell. A macro cell generally covers a relatively large geographic area (e.g., several kilometers in radius) and may allow unrestricted access by UEs with service subscriptions with the network provider. A small cell, such as a pico cell, would generally cover a relatively smaller geographic area and may allow unrestricted access by UEs with service subscriptions with the network provider. A small cell, such as a femto cell, would also generally cover a relatively small geographic area (e.g., a home) and, in addition to unrestricted access, may also provide restricted access by UEs having an association with the femto cell (e.g., UEs in a closed subscriber group (CSG), UEs for users in the home, and the like). A base station for a macro cell may be referred to as a macro base station. A base station for a small cell may be referred to as a small cell base station, a pico base station, a femto base station or a home base station. In the example shown in FIG. 1, base stations 105d and 105e are regular macro base stations, while base stations 105a-105c are macro base stations enabled with one of 3 dimension (3D), full dimension (FD), or massive MIMO. Base stations 105a-105c take advantage of their higher dimension MIMO capabilities to exploit 3D beamforming in both elevation and azimuth beamforming to increase coverage and capacity. Base station 105f is a small cell base station which may be a home node or portable access point. A base station may support one or multiple (e.g., two, three, four, and the like) cells.

Wireless network 100 may support synchronous or asynchronous operation. For synchronous operation, the base stations may have similar frame timing, and transmissions from different base stations may be approximately aligned in time. For asynchronous operation, the base stations may have different frame timing, and transmissions from different base stations may not be aligned in time. In some scenarios, networks may be enabled or configured to handle dynamic switching between synchronous or asynchronous operations.

UEs 115 are dispersed throughout the wireless network 100, and each UE may be stationary or mobile. It should be appreciated that, although a mobile apparatus is commonly referred to as a UE in standards and specifications promulgated by the 3GPP, such apparatus may additionally or otherwise be referred to by those skilled in the art as a mobile station (MS), a subscriber station, a mobile unit, a subscriber unit, a wireless unit, a remote unit, a mobile device, a wireless device, a wireless communications device, a remote device, a mobile subscriber station, an access terminal (AT), a mobile terminal, a wireless terminal, a remote terminal, a handset, a terminal, a user agent, a mobile client, a client, a gaming device, an augmented reality device, vehicular component, vehicular device, or vehicular module, or some other suitable terminology. Within the present document, a “mobile” apparatus or UE need not necessarily have a capability to move, and may be stationary. Some non-limiting examples of a mobile apparatus, such as may include implementations of one or more of UEs 115, include a mobile, a cellular (cell) phone, a smart phone, a session initiation protocol (SIP) phone, a wireless local loop (WLL) station, a laptop, a personal computer (PC), a notebook, a netbook, a smart book, a tablet, and a personal digital assistant (PDA). A mobile apparatus may additionally be an IoT or “Internet of everything” (IoE) device such as an automotive or other transportation vehicle, a satellite radio, a global positioning system (GPS) device, a global navigation satellite system (GNSS) device, a logistics controller, a drone, a multi-copter, a quad-copter, a smart energy or security device, a solar panel or solar array, municipal lighting, water, or other infrastructure; industrial automation and enterprise devices; consumer and wearable devices, such as eyewear, a wearable camera, a smart watch, a health or fitness tracker, a mammal implantable device, gesture tracking device, medical device, a digital audio player (e.g., MP3 player), a camera, a game console, etc.; and digital home or smart home devices such as a home audio, video, and multimedia device, an appliance, a sensor, a vending machine, intelligent lighting, a home security system, a smart meter, etc. In one aspect, a UE may be a device that includes a Universal Integrated Circuit Card (UICC). In another aspect, a UE may be a device that does not include a UICC. In some aspects, UEs that do not include UICCs may also be referred to as IoE devices. UEs 115a-115d of the implementation illustrated in FIG. 1 are examples of mobile smart phone-type devices accessing wireless network 100. A UE may also be a machine specifically configured for connected communication, including machine type communication (MTC), enhanced MTC (eMTC), narrowband IoT (NB-IoT) and the like. UEs 115e-115k illustrated in FIG. 1 are examples of various machines configured for communication that access wireless network 100.

A mobile apparatus, such as UEs 115, may be able to communicate with any type of the base stations, whether macro base stations, pico base stations, femto base stations, relays, and the like. In FIG. 1, a communication link (represented as a lightning bolt) indicates wireless transmissions between a UE and a serving base station, which is a base station designated to serve the UE on the downlink or uplink, or desired transmission between base stations, and backhaul transmissions between base stations. UEs may operate as base stations or other network nodes in some scenarios. Backhaul communication between base stations of wireless network 100 may occur using wired or wireless communication links.

In operation at wireless network 100, base stations 105a-105c serve UEs 115a and 115b using 3D beamforming and coordinated spatial techniques, such as coordinated multipoint (CoMP) or multi-connectivity. Macro base station 105d performs backhaul communications with base stations 105a-105c, as well as small cell, base station 105f. Macro base station 105d also transmits multicast services which are subscribed to and received by UEs 115c and 115d. Such multicast services may include mobile television or stream video, or may include other services for providing community information, such as weather emergencies or alerts, such as Amber alerts or gray alerts.

Wireless network 100 of implementations supports mission critical communications with ultra-reliable and redundant links for mission critical devices, such UE 115e, which is a drone. Redundant communication links with UE 115e include from macro base stations 105d and 105e, as well as small cell base station 105f. Other machine type devices, such as UE 115f (thermometer), UE 115g (smart meter), and UE 115h (wearable device) may communicate through wireless network 100 either directly with base stations, such as small cell base station 105f, and macro base station 105e, or in multi-hop configurations by communicating with another user device which relays its information to the network, such as UE 115f communicating temperature measurement information to the smart meter, UE 115g, which is then reported to the network through small cell base station 105f. Wireless network 100 may also provide additional network efficiency through dynamic, low-latency TDD communications or low-latency FDD communications, such as in a vehicle-to-vehicle (V2V) mesh network between UEs 115i-115k communicating with macro base station 105e.

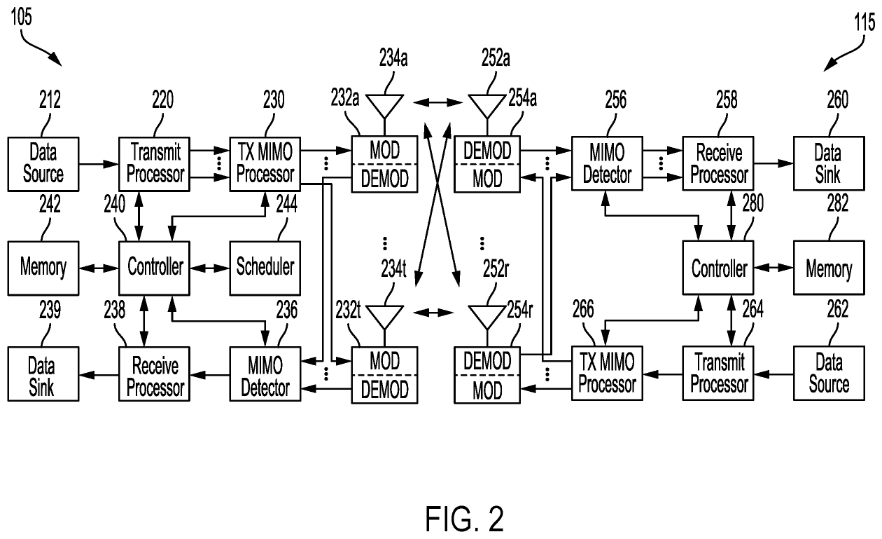

FIG. 2 is a block diagram illustrating examples of base station 105 and UE 115 according to one or more aspects. Base station 105 and UE 115 may be any of the base stations and one of the UEs in FIG. 1. For a restricted association scenario (as mentioned above), base station 105 may be small cell base station 105f in FIG. 1, and UE 115 may be UE 115c or 115d operating in a service area of base station 105f, which in order to access small cell base station 105f, would be included in a list of accessible UEs for small cell base station 105f. Base station 105 may also be a base station of some other type. As shown in FIG. 2, base station 105 may be equipped with antennas 234a through 234t, and UE 115 may be equipped with antennas 252a through 252r for facilitating wireless communications.

At base station 105, transmit processor 220 may receive data from data source 212 and control information from controller 240, such as a processor. The control information may be for a physical broadcast channel (PBCH), a physical control format indicator channel (PCFICH), a physical hybrid-ARQ (automatic repeat request) indicator channel (PHICH), a physical downlink control channel (PDCCH), an enhanced physical downlink control channel (EPDCCH), an MTC physical downlink control channel (MPDCCH), etc. The data may be for a physical downlink shared channel (PDSCH), etc. Additionally, transmit processor 220 may process (e.g., encode and symbol map) the data and control information to obtain data symbols and control symbols, respectively. Transmit processor 220 may also generate reference symbols, e.g., for the primary synchronization signal (PSS) and secondary synchronization signal (SSS), and cell-specific reference signal. Transmit (TX) MIMO processor 230 may perform spatial processing (e.g., precoding) on the data symbols, the control symbols, or the reference symbols, if applicable, and may provide output symbol streams to modulators (MODs) 232a through 232t. For example, spatial processing performed on the data symbols, the control symbols, or the reference symbols may include precoding. Each modulator 232 may process a respective output symbol stream (e.g., for OFDM, etc.) to obtain an output sample stream. Each modulator 232 may additionally or alternatively process (e.g., convert to analog, amplify, filter, and upconvert) the output sample stream to obtain a downlink signal. Downlink signals from modulators 232a through 232t may be transmitted via antennas 234a through 234t, respectively.

At UE 115, antennas 252a through 252r may receive the downlink signals from base station 105 and may provide received signals to demodulators (DEMODs) 254a through 254r, respectively. Each demodulator 254 may condition (e.g., filter, amplify, downconvert, and digitize) a respective received signal to obtain input samples. Each demodulator 254 may further process the input samples (e.g., for OFDM, etc.) to obtain received symbols. MIMO detector 256 may obtain received symbols from demodulators 254a through 254r, perform MIMO detection on the received symbols if applicable, and provide detected symbols. Receive processor 258 may process (e.g., demodulate, deinterleave, and decode) the detected symbols, provide decoded data for UE 115 to data sink 260, and provide decoded control information to controller 280, such as a processor.

On the uplink, at UE 115, transmit processor 264 may receive and process data (e.g., for a physical uplink shared channel (PUSCH)) from data source 262 and control information (e.g., for a physical uplink control channel (PUCCH)) from controller 280. Additionally, transmit processor 264 may also generate reference symbols for a reference signal. The symbols from transmit processor 264 may be precoded by TX MIMO processor 266 if applicable, further processed by modulators 254a through 254r (e.g., for SC-FDM, etc.), and transmitted to base station 105. At base station 105, the uplink signals from UE 115 may be received by antennas 234, processed by demodulators 232, detected by MIMO detector 236 if applicable, and further processed by receive processor 238 to obtain decoded data and control information sent by UE 115. Receive processor 238 may provide the decoded data to data sink 239 and the decoded control information to controller 240.

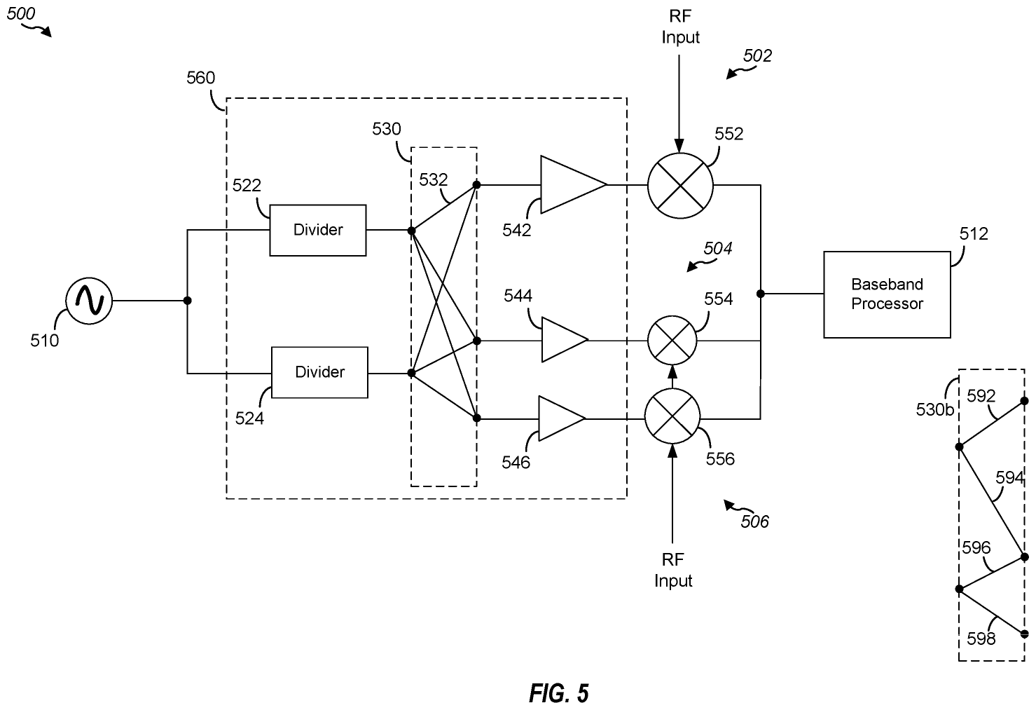

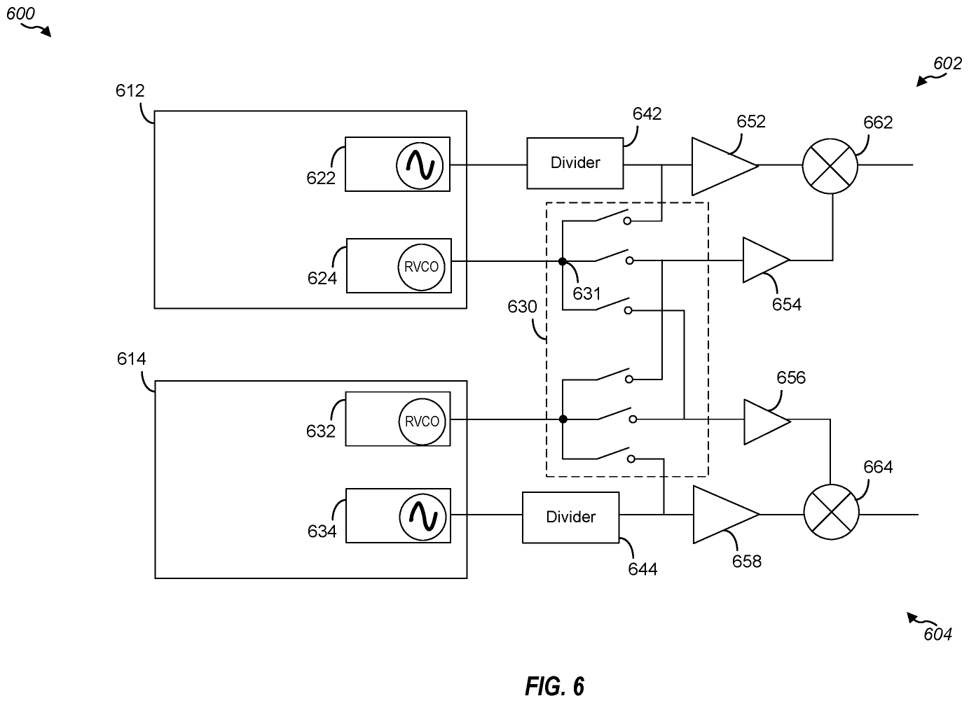

Controllers 240 and 280 may direct the operation at base station 105 and UE 115, respectively. Controller 240 or other processors and modules at base station 105 or controller 280 or other processors and modules at UE 115 may perform or direct the execution of various processes for the techniques described herein, such as to perform or direct the execution illustrated in FIG. 5 or FIG. 6, or other processes for the techniques described herein. Memories 242 and 282 may store data and program codes for base station 105 and UE 115, respectively. Scheduler 244 may schedule UEs for data transmission on the downlink or the uplink.

In some cases, UE 115 and base station 105 may operate in a shared radio frequency spectrum band, which may include licensed or unlicensed (e.g., contention-based) frequency spectrum. In an unlicensed frequency portion of the shared radio frequency spectrum band, UEs 115 or base stations 105 may traditionally perform a medium-sensing procedure to contend for access to the frequency spectrum. For example, UE 115 or base station 105 may perform a listen-before-talk or listen-before-transmitting (LBT) procedure such as a clear channel assessment (CCA) prior to communicating in order to determine whether the shared channel is available. In some implementations, a CCA may include an energy detection procedure to determine whether there are any other active transmissions. For example, a device may infer that a change in a received signal strength indicator (RSSI) of a power meter indicates that a channel is occupied. Specifically, signal power that is concentrated in a certain bandwidth and exceeds a predetermined noise floor may indicate another wireless transmitter. A CCA also may include detection of specific sequences that indicate use of the channel. For example, another device may transmit a specific preamble prior to transmitting a data sequence. In some cases, an LBT procedure may include a wireless node adjusting its own backoff window based on the amount of energy detected on a channel or the acknowledge/negative-acknowledge (ACK/NACK) feedback for its own transmitted packets as a proxy for collisions.

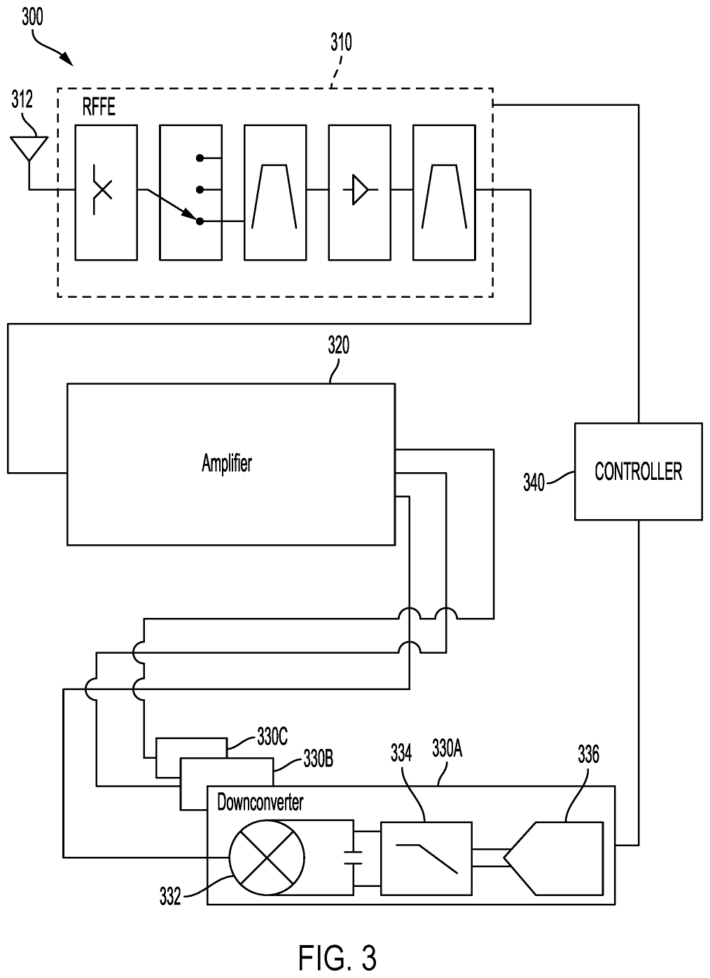

FIG. 3 is a block diagram illustrating a wireless receiver circuit 300 according to one or more aspects. In some embodiments, the receiver circuit 300 may be part of a converged sub-6 Ghz and mm Wave radio frequency (RF) transceiver, a sub-6 GHz radio frequency (RF) transceiver, or a mmWave radio frequency (RF) transceiver. In some embodiments, portions or all of the RF transceiver of FIG. 3 may be located in a single integrated circuit (IC) sharing a common substrate. The receiver circuit 300 may include an antenna 312 to receive radio frequency (RF) signals, such as a phase antenna array. The antenna 312 is coupled to a RF front-end (RFFE) 310, which may include duplexers, SAW filters, switches, LNAs, and/or other transmit or receive circuits for conditioning signals received from the antenna 312. In some embodiments, the RFFE 310 may include separate circuits for conditioning or otherwise processing sub-6 GHz signals, mmWave signals, satellite signals, and/or other signals. For example, the RFFE 310 may include a first plurality of circuits for conditioning a sub-6 GHz signal for further processing by other circuitry and a second plurality of circuits for conditioning a mmWave RF signal for further processing by other circuitry. The output of the RFFE 310 in this example may be an input RF signal to other circuitry comprising the conditioned sub-6 GHz signal and a conditioned mmWave IF signal. The RFFE 310 is coupled to an amplifier 320, such as a low noise amplifier (LNA). The amplifier 320 is coupled to one or more downconverters 330A, 330B, and 330C. Each of the downconverters 330A, 330B, and 330C may include mixers 332, baseband filters (BBFs) 334, and/or analog-to-digital converters (ADCs) 336. The downconverters 330A, 330B, 330C may include one or more harmonic rejection mixers (HRMs). In some embodiments, the amplifier 320 is shared on an IC with one or more of the RFFE 310 and/or the downconverters 330A, 330B, and 330C.

Interference between wireless signals received at antenna 312 and processed through RFFE 310, amplifier 320, and downconverters 330A-C complicates operation of the receiver circuit 300, particularly when processing a large range of potential frequencies. For example, co-location of processing paths for sub-6 Ghz and mmWave signals in an integrated circuit can create interference between the sub-6 GHz signal harmonics and the mmWave signals. Interference between sub-6 GHz signals and mmWave signals may occur because mmWave IF signals corresponding to mmWave RF signals received at an antenna from over-the-air may be located near to sub-6 GHz signals in frequency (e.g., within 1-6 GHz) and/or located at harmonics of the sub-6 GHz (e.g., at integer multiples of the sub-6 GHz signals).

Interference between wireless signals may be further complicated by carrier aggregation (CA) operation. Carrier aggregation (CA) involves the combination of one or more carrier RF signals to carry a single data stream. Carrier aggregation (CA) improves the flexibility of the wireless devices and improves network utilization by allowing devices to be assigned different numbers of carriers for different periods of time based, at least in part, on historical, instantaneous, and/or predicted bandwidth use by the wireless device. Thus, when a mobile device needs additional bandwidth, additional carriers may be assigned to that wireless device, and then de-assigned and re-assigned to other mobile devices when bandwidth demands change. As carriers are assigned and de-assigned from a mobile device, the interaction of wireless signals may change. For example, different carriers in CA may be in different bands, and certain bands may have harmonics that overlap and/or otherwise interfere with certain other bands.

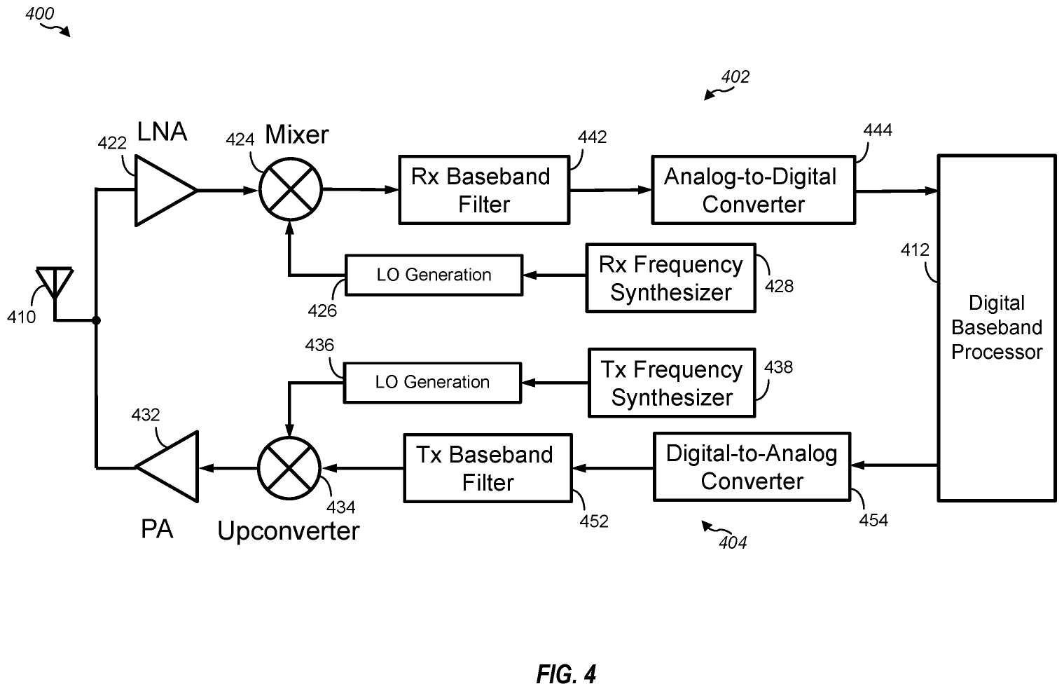

A controller 340 may detect conditions in the RF signal received from the antenna 312 or receive information regarding the carrier configuration from higher levels, such as a MAC layer or network layer. The controller 340 may configure components of the receiver circuit 300 to activate, deactivate, or control portions of the receiver circuit 300 to process an input RF signal. In some embodiments, the controller 340 configures components to reduce power consumption, calibrate components, and/or reduce interference between bands within the receiver circuit 300. In some embodiments, the controller 340 may configure local oscillator generation and cross routing (e.g., cross routing configuration) in one or more processing paths of mixers within the downconverters 330A, 330B, and 330C, as described further with reference to FIGS. 4-9.

As explained above, local oscillator (LO) circuits and/or components thereof may be duplicated for each transmit or receive chain of the device for different operating configurations. A majority of the power consumed by LO circuits (often referred to as an LO block) is consumed by mixer buffers (also referred to as LO buffers) of the LO circuit. The mixer buffers help process the LO signal before delivery to a corresponding mixer associated with the LO circuit and may provide improved isolation for other components. The LO circuit drives a corresponding mixer which receives the output (often referred to as an LO signal) of the LO circuit. The mixer also receives an RF signal for mixing with the LO signal and providing an output mixed signal to baseband circuitry for further processing in an RF front end circuit.

An LO circuit receives an input signal, often referred to as a synchronization signal or oscillator signal, from an oscillator or synchronization signal generator. The input signal to the LO circuit is often received by a divider (frequency divider) of the LO circuit which divides, reduces, the frequency of the input signal. The reduced frequency signal is then provided to the mixer buffer for processing before output as an LO signal to the mixer.

A particular device may include a plurality of transmit chains and receive chains, each of which may include one or more an LO circuits (each of which may have one or more dividers) and may include one or more mixers, such as for different operational modes, such as low/high power, low/high gain, etc. During operation, the individual chains may be turned on and off for different transmissions and when a chain is powered on, the individual chain may switch between low and high power modes. These high power modes may utilize multiple dividers and mixers (e.g., main and auxiliary components), and the lower pow mode may utilize only main components (e.g., main or primary divider, mixer buffer, and mixer).

However, main components may be roughly 1.5 to 2 times larger than the auxiliary components and consume much more power. Thus, using the main components in the low power mode still consumes a large share of the power of a regular or high power mode. Regular and low power modes cannot utilize the auxiliary components only due to issues caused by powering off the main or primary divider. For example, dividers of the LO circuit may cause phase issues when powered off and on. To illustrate, a divider may lose a phase setting and develop a phase difference between other chains (e.g., between dividers of other chains) when powering off. Accordingly, powering off the main or primary divider loses phase synchronization across the different transmit chains of the RF front end circuit and may cause transmission and/or reception issues, especially when it comes to beamforming.

In the aspects described herein, LO cross routing techniques and circuits are described to enable using less and/or lower power components for some operating modes to reduce power consumption for LO signal generation. In some such aspects, a primary or main divider may be used with auxiliary mixer buffers and/or mixers to retain divider synchronization across chains while also reducing power consumption. Accordingly, LO power consumption can be reduced and additional lower power operating modes may be utilized.

FIG. 4 is a circuit diagram illustrating a wireless transceiver circuit 400 according to one or more aspects. In some embodiments, the wireless receiver circuit 400 may be part of a sub-6 GHz radio frequency (RF) transceiver, a converged sub-6 Ghz and mm Wave radio frequency (RF) transceiver, or a mmWave radio frequency (RF) transceiver. In some embodiments, portions of the RF transceiver of FIG. 4 may be located in a single integrated circuit (IC) sharing a common substrate, and each portion may be coupled to each other and to a PCB.

The wireless transceiver circuit 400 includes a plurality of receive chains and plurality of transmit chains. In the example of FIG. 4, a single receive chain, first receive chain 402, and a single transmit chain, first transmit chain 404, are illustrated for simplicity. The wireless transceiver circuit 400 may include many more receive chains and/or transmit chains. The additional transmit or receive chains may be grouped together, such as groups of receive chains or groups of transmit chain. For example, in a particular implementation, the wireless transceiver circuit 400 may include 8 groups of 8 receive chains for a total of 64 receive chains. Each group of receive chains may include or correspond to a separate chip or portion of chip which is implemented on a PCB in some implementations.

The receive chains of the wireless transceiver circuit 400 may include or correspond to receive chains, feedback receive chains, or a combination thereof. Although the example of FIG. 4 is directed to an example of receive (RX) chains, in other implementations the receive chains may be feedback receive (FBRX) chains and have similar or identical operation.

Each receive chain may include a corresponding amplifier, mixer, and LO generation circuitry. For example, the first receive chain 402 includes an amplifier 422, a mixer 424 (e.g., downconverter), and LO generation circuitry 426. Each receive chain may be configured to receive multiple types of input signals. For example, each receive chain may be configured to receive a corresponding respective received signal from a corresponding antenna, such as antenna 410 and/or calibration signals.

Each transmit chain may include a corresponding amplifier, mixer, and LO generation circuitry. For example, the first transmit chain 404 includes an amplifier 432, a mixer 424 (e.g., upconverter), and LO generation circuitry 436. Each transmit chain may be configured to receive multiple types of input signals. For example, each transmit chain may be configured to receive a corresponding respective signal for transmission by a corresponding antenna, such as antenna 410 and/or calibration signals.

The amplifier, amplifier 422, of each receive chain may include or correspond to a low noise amplifier or other type of amplifier in a receive chain. In some implementations, the amplifier may include or correspond to a linear amplifier. The amplifier is configured to amplify received input signals, such as the received RF signals from a corresponding antenna. The amplifier 432 of each transmit chain may include or correspond to a power amplifier or other type of amplifier in a transmit chain. In some implementations, the amplifier may include or correspond to a linear amplifier. The amplifier is configured to amplify received input signals, such as the RF signals to be transmitted by a corresponding antenna.

The mixer, mixers 424 and 434, of each chain may include or correspond to a frequency mixer or multiplier configured to generate a new signal, including or having one or more new frequencies, based on two signals applied to it, such as the difference of the frequencies of the two signals applied to it. Each mixer is configured to generate an output based on a corresponding pair of an input signal and a local oscillator signal. In the example of FIG. 4, the input signal may include or correspond to received signals from a corresponding antenna or a common reference or calibration signal common to one or more of the chains, and the local oscillator signal may include or correspond to an adjusted (e.g., divided or reduced) local oscillator signal that is received from an external local oscillator (e.g., external phase locked loop (PLL)) and adjusted based on a corresponding on-chip divider. The mixer may include or correspond to mixer, a single balanced mixer, or a double balanced mixer. The mixer may include one or more circuit components such as transistors or diodes to generate the output.

The LO generation circuitry, LO generation circuitry 426 and 436, of each chain may include or correspond to circuitry configured to generate a LO signal based on a synchronization signal or clock signal from signal generation circuitry, such as the frequency synthesizers 428 or 438. Examples of LO generation circuitry are described further with reference to FIGS. 5-9.

The frequency synthesizers 428 and 438 of each chain may include or correspond to synchronization signal or clock signal generation circuitry. For example, the frequency synthesizers 428 and 438 may be configured to generate a signal with a particular frequency for LO processing and LO signal generation for mixing or upconverting. The LO signal may enable further baseband processing (e.g., baseband filtering) for receiving RF signals and generation of RF signals for transmission. Examples of frequency synthesizers are described further with reference to FIGS. 5 and 6.

With this architecture of each chain receive and/or transmit chain having a corresponding LO generation circuit and being capable of performance in many modes, the wireless transceiver circuit 400 may have many complicated LO generation circuits with multiple mixer buffers. Additionally, the wireless transceiver circuit 400 may include multiple mixers for each chain, as shown and described with reference to FIGS. 5-9. For example, each receive chain may have additional auxiliary mixers used for different operational modes. Utilizing all of these components (e.g., mixer buffers and mixers), and especially primary or main versions of these components, can require significant power usage.

In addition, with this architecture of each receive chain having a corresponding divider or LO signal, the wireless transceiver circuit 400 may accumulate a phase difference or misalignment between dividers over time. For example, the dividers may experience a phase misalignment due to powering up and down individual receive chains during operation (e.g., MIMO/OFDM operations), from external interference (e.g., noise, RF energy, sunburst, cosmic ray, etc.), from a power supply (power supply ringing), etc., or a combination thereof.

The receiver baseband filter 442 of each receive chain may include or correspond to filter circuitry configured to filter out signals outside of baseband frequencies generated by the mixer 424.

The ADC 444 of each receive chain may include or correspond to ADC circuitry configured to convert a received analog signal back to its digital signal, sequence of bits, it was created from. For example, a signal with varying frequency and/or amplitude may be converted to a sequence of bits with bit values corresponding to the frequency and/or amplitude.

The transmit baseband filter 452 of each of each transmit chain may include or correspond to transmit baseband filter circuitry configured to filter the converted analog signal for mixing and transmission by the antenna 410.

The DAC 454 of each transmit chain may include or correspond to DAC circuitry configured to convert a digital signal, e.g., a sequence of bits, to an analog signal, such as a signal with varying frequency and/or amplitude which indicates or corresponds to bit values of the sequence.

The wireless transceiver circuit 400 includes one or more antennas, such as antenna 410, and a digital baseband processor 412. The antenna 410 is configured to transmit and receive RF energy corresponding to RF signals. The digital baseband processor 412 includes or correspond digital baseband processing circuitry and is configured to process data for transmission and to process data from received RF signals.

The digital baseband processor 412 is configured to receive outputs from the receive chains and process the output of the receive chains. For example, the digital baseband processor 412 is configured to receive a corresponding digital output (e.g., a sequence of zeros and ones corresponding to the filtered analog signal) from each receive chain of the plurality of receive chains 402-408 and to perform baseband processing on the output.

Although the digital baseband processor 412 is coupled to the output of the respective ADC of each receive chain and configured to receive a respective output of each receive chain in FIG. 4, the output of receive chain may bypass the digital baseband processor 412 in some implementations, such as by the use of switches, traces, or other bypass circuitry. For example, during calibration, the output of each receive chain may physically bypass the digital baseband processor 412 and be directed to RF calibration processing or may pass through the digital baseband processor 412 without the digital baseband processor 412 processing the signal.

Additionally, the digital baseband processor 412 is configured to generate signals for wireless transmission. For example, the digital baseband processor 412 is configured to receive data and generate one or more sequences of bits for conversion to an analog signal based on and/or indicating the data.

In the aspects described herein, the LO generation circuitry 426 and 436 include LO cross route circuitry that is configurable to enable the wireless transceiver circuit 400 to select different components of the LO generation circuitry for operation. The LO cross route circuitry provides additional and flexible pathways for LO circuits to enable configurable routing of synchronization signals from the frequency synthesizers to different dividers, mixer buffers, mixers, and/or upconverters. In some implementations, an LO cross route is added between frequency dividers and mixer buffers and enables configurable paths to route divider outputs to different mixers/upconverters based on gain modes or power modes. For example, a particular or primary divider can be kept on and provide its output to one or more auxiliary mixer buffers for a regular or lower power mode. Examples of such circuits and operations are described further with reference to FIG. 5.

Additionally, or alternatively, an LO cross route may be added between LO blocks of different chains and enables configurable paths to route different synthesizer signals (oscillator or input signal) to different mixers buffers based on gain modes or power modes. For example, a lower power mode synchronization signal can be provided to auxiliary mixers of its chain or another chain. Providing synchronization signals across chains may improve isolation and enable calibration of LO generation circuit and components thereof. For example, with LO cross route circuitry, a mixer can receive an RF input from one synthesizer and an LO input from another synthesizer. In the second example, the LO cross route circuitry receives signals from oscillators and not from dividers, as in the first example, and may provides additional or different cross routing options across chains. Examples of such circuits and operations are described further with reference to FIG. 6.

In some implementations, the LO cross route circuitry may enable residual sideband (RSB) calibration on two or more transmit or receive paths simultaneously. For example, RSB calibration may be performed on two downlink/receive paths, and may include providing a first PLL output (PLL1) of a low power mode (LPM) from a first receive chain via the LO cross route circuitry to the RF port of a second mixer on a second receive chain via an auxiliary buffer of the second receive chain. Additionally, a second PLL output (PLL2) of a low power mode (LPM) from the second receive chain may be provided via the LO cross route circuitry to the RF port of a first mixer on the first receive chain via an auxiliary buffer of the first receive chain. The mixer RF and LO isolation for each mixer/chain is significantly improved because the respective input signals are from LO circuitry/synthesizers on a different chain. Examples of such circuits and operations are described further with reference to FIG. 6.

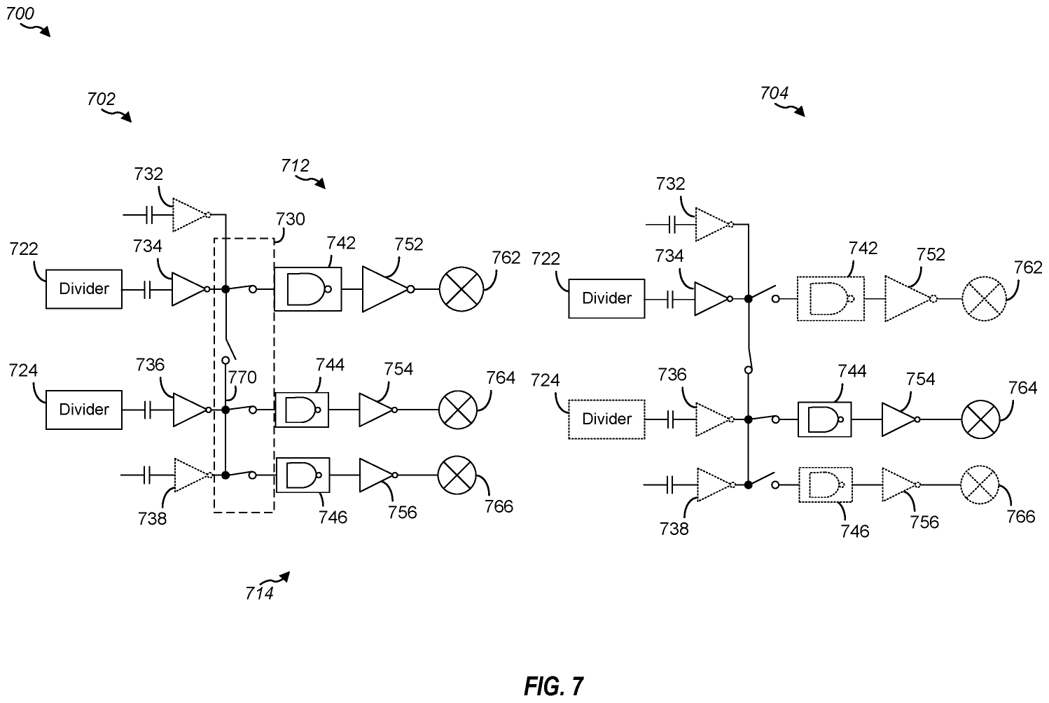

The LO cross route circuitry described herein applies to both receive and transmit chains, and also applies to different frequency bands. The particular configuration of the LO blocks and the LO cross route circuitry may depend on implementation details and a corresponding operational frequency and bandwidth. For example, a device may include different LO blocks, such as for new radio unlicensed (NRU), low, medium, high frequency bands (LMH), and millimeter wave (mmW), each of which may have a different configuration, as illustrated and described with reference to FIGS. 7-9.

Accordingly, the wireless transceiver circuit 400 may be able to more efficiently perform reception and transmission operations by utilizing the LO cross route circuitry of the LO generation circuitry. Improved efficiency through enhanced and configurable selection of components reduces overall power consumption and enables longer battery life. Accordingly, the device performance and experience may be increased due to the reduction in power usage.

FIG. 5 is a circuit diagram illustrating a wireless receiver circuit 500 according to one or more aspects. In some embodiments, the wireless receiver circuit 500 may be part of a sub-6 GHz radio frequency (RF) transceiver, a converged sub-6 Ghz and mmWave radio frequency (RF) transceiver, or a mmWave radio frequency (RF) transceiver. In some embodiments, portions of the RF receiver (or transceiver) of FIG. 5 may be located in a single integrated circuit (IC) sharing a common substrate, and each portion may be coupled to each other and to a PCB.

The wireless receiver circuit 500 includes a plurality of receive chains, a synchronization signal generator 510 and a baseband processor 512. In FIG. 5, one exemplary receive chain is illustrated for simplicity. Each receive chain of the wireless receiver circuit 500 may include a primary chain or path and one or more auxiliary chains or paths. In the example of FIG. 5, the receive chain includes a primary chain or path 502 and two auxiliary chains or paths, 504 and 506. The wireless receiver circuit 500 may include many more receive chains and groups of receive chains. For example, in a particular implementation, the wireless receiver circuit 500 may include 8 groups of 8 receive chains for a total of 64 receive chains. Each group of receive chains may include or correspond to a separate chip or portion of chip which is implemented on a PCB.

The synchronization signal generator 510 may include or correspond to the receive frequency synthesizer 428, the transmit frequency synthesizer 438, or both, of FIG. 4. For example, the synchronization signal generator 510 may be configured to generate a clock signal or synchronization signal for further processing and for LO signal generation. The synchronization signal generator 510 may include or correspond to signal generation circuitry, such as an oscillator. As illustrative, non-limiting examples, the synchronization signal generator 510 may include or correspond to a PLL, a delay-locked loop (DLL), a voltage-controlled oscillator (VCO), a ring VCO (RVCO), an inductance-capacitance VCO (LCVCO), etc., or any combination thereof.

The baseband processor 512 may include or correspond to the digital baseband processor 412 of FIG. 4. In some implementations, the baseband processor 512 includes a baseband filter or is configured to perform baseband filtering. In other implementations, the wireless receiver circuit 500 further includes a baseband filter separate from the baseband processor 512. The wireless receiver circuit 500 may also be coupled to an antenna, such as antenna 410 of FIG. 4, and configured to receive RF energy received by the antenna. For example, mixers of the wireless receiver circuit 500 may be configured to receive amplified RF energy from the antenna (e.g., an RF input as shown in FIG. 5).

In the example of FIG. 5, the receive chain includes a divider for the primary path and a shared or joint divider for one or more alternative paths, such as divider 522 (e.g., a main or primary divider) and divider 524 (e.g., a secondary or auxiliary divider). Each path of the receive chain includes a mixer buffer and a mixer, such as mixer buffers 542, 544, and 546. The mixer buffers are connected to the dividers via LO cross route circuitry 530, and mixers 552, 554, and 556.

The LO cross route circuitry 530 includes a plurality of paths, paths 532, configured to couple one or more of the dividers to one or more of mixers, via the corresponding mixer buffer. For example, the LO cross route circuitry 530 includes paths between the divider of the primary path, divider 522, to mixers, mixers 554 and 556, of the auxiliary paths. As another example, the LO cross route circuitry 530 includes paths between the divider of the auxiliary path, divider 524, to the mixer, mixer 552, of the primary path. These additional routing paths for the synchronization signal generated by the synchronization signal generator 510 (e.g., oscillator thereof) enable additional operational modes and power savings in the additional operational modes. For example, one or more auxiliary mixers may be used in a particular low power mode instead of using the main mixer. As the auxiliary mixers are generally smaller and have a lower power consumption, a power savings can be achieved by utilizing the additional paths from the LO cross route circuitry 530.

Additionally, the LO cross route circuitry 530 may enable a particular divider, such as a main divider (e.g., divider 522), to remain powered on during more or all operational modes to ensure phase alignment with other dividers and phase alignment between chains of the wireless receiver circuit 500. To illustrate, when a divider is powered off and then back on, it will default to a random possible state, such as 0 or 180 degrees for a divider with a divide by two function or 0, 90, 180, or 270 degrees for a divider with a divide by four function. This random behavior can cause consequences for phase alignment and receiver operation when powering down and up chains.

The divider, dividers 522 and 524, of each receive chain may include or correspond to a frequency divider. The divider of each receive chain is arranged as a local oscillator (LO) driven divider (often referred to as LO dividers) and is configured to reduce or divide a frequency of a received synchronization signal (also referred to as a LO signal) and provide the reduced synchronization signal (or LO signal) to a corresponding mixer. Alternatively, the signal received at the divider may include or correspond to an external clock signal, such as output of a PLL or VCO, and the output from the divider may include or correspond to a LO signal.

The mixer buffers, mixer buffers 542, 544, and 546, of each receive chain may include or correspond to mixer buffer circuitry or other type of buffer circuit for a mixer in a receive chain. The mixer buffers 542, 544, and 546 may include or correspond to circuitry or components which are configured to process the divided synchronization signal (e.g., LO signal or unprocessed LO signal) before delivery to a corresponding mixer for the LO circuit and may provide improved isolation for other components.

The mixer, mixers 552, 554, and 556, of each receive chain may include or correspond to a frequency mixer or multiplier configured to generate a new signal, including or having one or more new frequencies, based on two signals applied to it, such as the difference of the frequencies of the two signals applied to it. Each mixer 552, 554, and 556 is configured to generate an output based on a corresponding pair of an input signal and a local oscillator signal. In the example of FIG. 5, the input signal may include or correspond to received wireless communication signals from a corresponding antenna, and the local oscillator signal may include or correspond to an adjusted (e.g., divided or reduced) local oscillator signal that is received from an external local oscillator or clock signal (e.g., external PLL) and adjusted based on a corresponding on-chip divider. The mixer of each receive chain may include or correspond to an unbalanced mixer, a single balanced mixer, or a double balanced mixer. The mixer may include one or more circuit components such as transistors or diodes to generate the output.

Box 560 corresponds to what is commonly reference to as LO block or LO generation circuit, such as the LO generation circuits with cross routing, LO generation circuitry 426 and 436 of FIG. 4. As illustrated in FIG. 5, box 560 includes the dividers 522 and 524, the LO cross route circuitry 530, and the mixer buffers 542, 544, and 546. In some implementations, the LO generation circuit further includes synchronization signal generator circuitry (e.g., oscillator of the synchronization signal generator 510), the mixers 552, 554, and 556, or a combination thereof.

During operation, a RF signal is received by the antenna and provided to one or more mixers of the RF chain of the wireless receiver circuit 500 illustrated in FIG. 5. To process the received RF signal at the mixer(s), a LO signal or signals are generated and provided to the mixers. The mixer process (e.g., mix) the two signals to generate a processed, mixed or baseband signal for further/baseband processing by the baseband processor 512.

In some operational modes, such as full or non-reduced power modes, the components of the primary path 502 are powered on and generate an LO signal. In such operational modes, one or more components of one or more auxiliary paths 504 and 506 may also be powered on and generate an LO signal or LO signals, such as auxiliary LO signals for the auxiliary LO mixers.

For example, the synchronization signal generator 510 generates a clock or synchronization signal, synchronization signal, and provides the synchronization signal to the divider 522 of the primary path 502 and to the divider 524 of the auxiliary paths 504 and 506. The LO cross route circuitry 530 provides a first reduced synchronization signal from the divider 522 to the mixer buffer 542 of the primary path 502. The mixer buffer 542 process the first reduced synchronization signal to generate a first LO signal and provides the first LO signal to the mixer 552 (e.g., main mixer) of the primary path 502. The mixer 552 processes (mixes) the RF input and LO signal and generates a first mixed signal. The mixer 552 provides the first mixed signal to the baseband processor 512 for further receive processing.

Additionally, the LO cross route circuitry 530 provides a second reduced synchronization signal from the divider 524 to the mixer buffers 544 and 546 of the auxiliary paths 504 and 506. The mixer buffers 544 and 546 process the second reduced synchronization signal to generate corresponding LO signals and provide the LO signals to their corresponding mixers, mixers 554 and 556 (e.g., auxiliary mixers) of the auxiliary paths 504 and 506. The mixers 554 and 556 process (mix) the RF input and LO signal and generate a corresponding mixed signal. The mixers 554 and 556 provide the mixed signals to the baseband processor 512 for further receive processing.

In some other operational modes, such as reduced power modes, the components of the primary path 502 are not powered on or only selected components of the primary path are powered on. In such operational modes, one or more components of one or more auxiliary paths 504 and 506 are powered on and generate an LO signal for processing the received RF signal. To illustrate, in a particular low power mode, the synchronization signal generator 510 generates a clock or synchronization signal, synchronization signal, and provides the synchronization signal to the divider 522 of the primary path 502. The divider 522 process the synchronization signal, such as reduces the frequency of the synchronization signal by two or four, and provides the reduced synchronization signal to the LO cross route circuitry 530. The LO cross route circuitry 530 provides the reduced synchronization signal received from or on the primary path 502 to components of one or more of the auxiliary paths. For example, the LO cross route circuitry 530 provides the reduced synchronization signal from the divider 522 (of the primary path 502) to the mixer buffer 544 of the auxiliary path 504. The mixer buffer 544 process the reduced synchronization signal to generate an LO signal and provides the LO signal to the mixer 554 (e.g., auxiliary mixer) of the auxiliary path 504. The mixer 554 processes (mixes) the RF input and LO signal and generates a mixed signal. The mixer 554 provides the mixed signal to the baseband processor 512 for further receive processing.

Although operations for particular operational or power modes are described in FIG. 5, the wireless receiver circuit 500 may perform additional or alternative operations in other power modes. For example, the wireless receiver circuit 500 may utilize components of multiple auxiliary chains in some low power modes. As another example, the wireless receiver circuit 500 may not utilize any components of the primary chain 502 in some low power modes.

In FIG. 5, the LO cross route circuitry 530 enables additional paths (cross routes or cross routing) between component paths of a receive chain. In the example of FIG. 5, the LO cross route circuitry 530 provide additional paths between dividers and mixer buffers of a LO generation circuit. In other examples, the LO cross route circuitry 530 may provide additional paths between dividers and mixers, between signal generations and dividers, signal generations and mixers/mixer buffers, or a combination thereof.

Although FIG. 5 illustrates an example where the LO cross route circuitry 530 includes a plurality of paths, such as all possible paths between the main or primary chain and the auxiliary chain, in other examples the LO cross route circuitry may have only a portion of the possible routes or select routes between the main and auxiliary receive chains. For example, as illustrated in alternative LO cross route circuit 530b the alternative LO cross route circuit 530b only includes paths 592-598. To illustrate, the LO cross route circuit 530b includes a primary path 592 from divider 522 to mixer buffer 542, a single primary to alternative path 594 from divider 522 to mixer buffer 544, and alternative or HRM paths 596 and 598 from divider 524 to mixer buffer 544 and mixer buffer 546 respectively.

An HRM path may include components of or corresponding to a harmonic rejection mixer and/or a harmonic rejection mixer buffer. For example, the auxiliary mixer may be used in connection with the mixer to perform harmonic rejection mixing operations and the combination of the main mixer and auxiliary mixer or mixers may be referred to as a harmonic rejection mixer. Additionally, a harmonic rejection mixer buffer may include the main mixer buffer and one or more auxiliary mixer buffers.

In addition, although the example of FIG. 5 illustrates LO cross route circuitry 530 that provides additional path between component paths of a single receive chain, in other examples, the LO cross route circuitry 530 provides additional paths between component chains of different receive and/or transmit chains, such as described further with reference to FIG. 6.

FIG. 6 is a circuit diagram illustrating a wireless receiver circuit 600 according to one or more aspects. In some embodiments, the wireless receiver circuit 600 may be part of a sub-6 GHz radio frequency (RF) transceiver, a converged sub-6 Ghz and mmWave radio frequency (RF) transceiver, or a mmWave radio frequency (RF) transceiver. In some embodiments, portions of the RF receive (or transceiver) of FIG. 6 may be located in a single integrated circuit (IC) sharing a common substrate, and each portion may be coupled to each other and to a PCB.

The wireless receiver circuit 600 includes a plurality of receive chains (a first chain 602 and a second chain 604) and LO cross route circuitry 630. Similar to FIG. 5, the wireless receiver circuit 600 of FIG. 6 may be coupled to a baseband filter and an antenna and configured to receive RF signals and transmit RF signals. In FIG. 6, two receive chains are illustrated for simplicity.

In the example of FIG. 6, each receive chain of the receive chains 602 and 604 includes a divider for the primary path, dividers 642 and 644, and does not include a divider for one or more alternative paths, such as divider 522 or divider 524 (e.g., secondary or auxiliary dividers) as in FIG. 5. Each path of the receive chain includes a corresponding mixer buffer, such as mixer buffers 652-658, and a single mixer, such as mixers 662 and 664. As compared to the wireless receiver circuit 500 of FIG. 5, the wireless receiver circuit 600 of FIG. 6 does not include multiple mixers per chain, such as no auxiliary mixers per chain.

The divider, dividers 642 and 644, of each receive chain may include or correspond to a frequency divider, as described with reference to FIGS. 4 and 5. The dividers are configured to reduce or divide a frequency of a received synchronization signal (also referred to as a LO signal) and provide the reduced synchronization signal (or LO signal) to a corresponding mixer via a mixer buffer.

The mixer buffers, mixer buffers 652-658, of each the receive chains may include or correspond to mixer buffer circuitry or other type of isolation or buffer circuitry for a mixer in a receive chain. The mixer buffers 652-658 may include or correspond to circuitry or components which are configured to process the divided synchronization signal (e.g., LO signal or unprocessed LO signal) before delivery to a corresponding mixer for the LO circuit and may provide improved isolation for other components. As illustrative examples, the mixer buffer circuitry may include or correspond to capacitors, logic gates (e.g., NAND gates), buffers, etc., or a combination thereof. For example, the mixer buffer circuitry may include or correspond to multiple stage mixer buffer circuitry including multiple components arranged serially, such as described further with reference to FIGS. 7-9.

The mixer, mixer 662 and 664, of each receive chain 602 and 604 may include or correspond to a frequency mixer or multiplier configured to generate a new signal, including or having one or more new frequencies, based on two signals applied to it, such as the difference of the frequencies of the two signals applied to it. Each mixer 662 and 664 is configured to generate an output based on a corresponding pair of an input signal and a local oscillator signal, as described with reference to FIGS. 4 and 5, and may include or correspond to the mixers described with reference to FIGS. 4 and 5.

Each receive chain 602 and 604 of the wireless receiver circuit 600 may include synchronization signal generator circuitry that includes one or more synchronization signal generators. For example, receive chain 602 (first receive chain) includes synchronization signal generator circuitry 612, and the synchronization signal generator circuitry 612 includes a first synchronization signal generator 622 (e.g., a LCVCO signal generator) and a second synchronization signal generator 624 (e.g., a RVCO signal generator). The different synchronization signal generators may include or correspond to synchronization signal generators for different modes, such as high power modes and low power modes. To illustrate, the first synchronization signal generator 622 (e.g., a LCVCO signal generator) may be for a high power mode and the second synchronization signal generator 624 (e.g., a RVCO signal generator) may be for a low power mode.

Receive chain 604 (second receive chain) includes synchronization signal generator circuitry 614, and the synchronization signal generator circuitry 614 includes a first synchronization signal generator 632 (e.g., a RVCO signal generator) and a second synchronization signal generator 634 (e.g., a LCVCO signal generator). The different synchronization signal generators may include or correspond to synchronization signal generators for different modes, such as high power modes and low power modes. To illustrate, the first synchronization signal generator 632 (e.g., a RVCO signal generator) may be for a low power or performance mode and the second synchronization signal generator 634 (e.g., a LCVCO signal generator) may be for a high power or performance mode. The synchronization signal generator circuitry 612 and/or 614 of FIG. 6 may include or correspond to the receive frequency synthesizer 428, the transmit frequency synthesizer 438, or both, of FIG. 4, the synchronization signal generator 510 of FIG. 5, or a combination thereof.

Each receive chain 602 and 604 of the wireless receiver circuit 600 may include a primary chain or path and one or more auxiliary chains or paths, similar to the example of FIG. 4. In the example of FIG. 6, the receive chain 602 includes a primary path and multiple auxiliary paths. To illustrate, the primary path (e.g., high power path) of the receive chain 602 includes the synchronization signal generator 622, the divider 642, the mixer buffer 652, and the mixer 662. A first auxiliary path (e.g., first on-chain low power path) of the receive chain 602 includes the synchronization signal generator 624, the mixer buffer 652, and the mixer 662. A second auxiliary path (e.g., second on-chain low power path) of the receive chain 602 includes the synchronization signal generator 624, the mixer buffer 654, and the mixer 662. A third auxiliary path (e.g., off-chain low power path or calibration path) of the receive chain 602 includes the synchronization signal generator 624, the mixer buffer 656, and the mixer 664. The second and third auxiliary paths may have reduced power consumption as compared to the first auxiliary path as they utilize auxiliary or smaller mixer buffers, such as mixer buffer 654 or 656.

The receive chain 604 also includes a primary path and multiple auxiliary paths. To illustrate, the primary path (e.g., high power path) of the receive chain 604 includes the synchronization signal generator 634, the divider 644, the mixer buffer 658, and the mixer 664. A first auxiliary path (e.g., first on-chain low power path) of the receive chain 604 includes the synchronization signal generator 632, the mixer buffer 656, and the mixer 664. A second auxiliary path (e.g., second on-chain low power path) of the receive chain 604 includes the synchronization signal generator 632, the mixer buffer 658, and the mixer 662. A third auxiliary path (e.g., off-chain low power path or calibration path) of the receive chain 604 includes the synchronization signal generator 632, the mixer buffer 654, and the mixer 662. The first and third auxiliary paths may have reduced power consumption as compared to the second auxiliary path as they utilize auxiliary or smaller mixer buffers, such as mixer buffer 654 or 656.

The wireless receiver circuit 600 may include many more receive chains and groups of receive chains. For example, in a particular implementation, the wireless receiver circuit 600 may include 8 groups of 8 receive chains for a total of 64 receive chains. Each group of receive chains may include or correspond to a separate chip or portion of chip which is implemented on a PCB. In FIG. 6, two receive chains are illustrated for simplicity. Similar to FIG. 5, the wireless receiver circuit 600 of FIG. 6 may be coupled to a baseband filter and an antenna and configured to receive RF signals and transmit RF signals.

In the example of FIG. 6, the LO cross route circuitry 630 of the wireless receiver circuit 600 is coupled to synchronization signal generator circuitry 612 and 614 and is configured to receive synchronization signals from the synchronization signal generator circuitry 612 and 614 and not from the dividers. To illustrate, the LO cross route circuitry 630 does not receive signals from a divider or dividers, such as divided synchronization signals or LO signals. Rather, the LO cross route circuitry 630 of FIG. 6 receives synchronization signal from the synchronization signal generator circuitry 612 and 614, such as low power or performance synchronization signals from particular types of synchronization signal generators (e.g., synchronization signal generators 624 and 632). In some examples, the LO cross route circuitry 630 may receive low power synchronization signals directly from synchronization signal generators. The LO cross route circuitry 630 is configured to provide the received synchronization signals to one or more mixer buffers. In the example of FIG. 6, the LO cross route circuitry 630 is configured to selectively provide the received synchronization signals to main or auxiliary mixer buffers of the receive chain of the synchronization signal generator, and additionally to one or more auxiliary mixer buffers of one or more additional receive chains. Providing synchronization signals across chains enables additional low power operational modes and enables chain calibration (e.g., calibration of components across chains of the receiver). Additionally, providing synchronization signals across chains may enable operations where a divider (e.g., main divider) is not powered down to reduce phase misalignment from divider power on.

The LO cross route circuitry 630 includes a plurality of paths, paths 631, configured to provide the synchronization signals to different mixer buffers. For example, the LO cross route circuitry 630 selectively provides the synchronization signal received from or on the receive chain 602 to a main mixer buffer of the receive chains, to an auxiliary mixer buffer of the receive chain 602, or the auxiliary mixer buffer of the receive chain 604.

Specifically, the LO cross route circuitry 630 includes paths from the synchronization signal generators 624 and 632 to mixer buffers 652-658. These additional routing paths for the synchronization signals enable additional operational modes and power savings in the additional operational modes. For example, one or more auxiliary mixer buffers may be used in a particular low power mode instead of using the main mixer buffer. As the auxiliary mixer buffers are generally smaller and have a lower power consumption then main mixer buffers, a power savings can be achieved by utilizing the additional paths from the LO cross route circuitry 630.

During operation, a RF signal is received by the antenna and provided to one or more mixers of the RF chain of the wireless receiver circuit 600 illustrated in FIG. 6. To process the received RF signal at the mixer(s), a LO signal or signals are generated and provided to the mixers. The mixer process (e.g., mix) the two signals to generate a processed, mixed or baseband signal for further/baseband processing by a baseband processor, such as the baseband processor 412 of FIG. 4 or the baseband processor 512 of FIG. 5.

In some operational modes, such as full or non-reduced power modes, the components of the primary paths of one or more receive chains (e.g., receive chains 602 and/or 604) are powered on and generate an LO signal. In such operational modes, one or more components of one or more auxiliary paths 504 and 506 may also be powered on and generate an LO signal or LO signals, such as auxiliary LO signals for the auxiliary LO mixer buffer.

In some other operational modes, such as reduced power modes or calibration modes, the components of the primary path of one or more receive chains (e.g., receive chains 602 and/or 604) are not powered on or only select components of the primary path are powered on. In such operational modes, one or more components of one or more auxiliary paths are powered on and generate an LO signal for processing the received RF signal. To illustrate, in a particular calibration mode, the synchronization signal generator 624 generates a clock or synchronization signal, first synchronization signal, and provides the first synchronization signal to the mixer buffer 656 (e.g., auxiliary mixer buffer) of the receive chain 604 via the LO cross route circuitry 630.

The mixer buffer 656 process first synchronization signal and provides the processed the synchronization signal (LO signal) to the mixer 664. The mixer 664 processes (mixes) the RF input and LO signal and generates a mixed signal. The mixer 664 provides the mixed signal to the baseband processor (not shown in FIG. 6) for further receive processing, such as calibration processing.

Similarly, the second receive chain 604 may generate a synchronization signal which is provided to the auxiliary mixer buffer and mixer of the first receive chain 602 for the calibration operation. To illustrate, the synchronization signal generator 632 generates a clock or synchronization signal, second synchronization signal, and provides the second synchronization signal to the mixer buffer 654 (e.g., auxiliary mixer buffer) of the first receive chain 602 via the LO cross route circuitry 630. The mixer buffer 654 process the second synchronization signal and provides the processed second synchronization signal (LO signal) to the mixer 662.

The mixer 662 processes (mixes) the RF input and LO signal and generates a second mixed signal. The mixer 662 provides the mixed signal to the baseband processor (not shown in FIG. 6) for further receive processing, such as calibration processing. Calibration processing may be based on the two received mixed signals which were processed by components of other chains. In some such implementations, the RF input may include or correspond to a calibration signal. Alternatively, in other such implementations no RF input or calibration signal is received at the mixers.

As another illustration, in a particular low power mode, the low power mode synchronization signal generators of one or more receive chains may generate a clock or synchronization signal, LPM synchronization signal, and provides the LPM synchronization signal to the corresponding mixer buffer and mixer of the same chain. For example, the LO cross route circuitry 630 receives a LPM synchronization signal from the synchronization signal generator 624 and provides the LPM synchronization signal to the auxiliary mixer buffer 654 and the mixer 662. By using the auxiliary mixer buffer 654 instead of the main mixer buffer 652, less power may be used. In some such operations, the LO cross route circuitry 630 does not provide the LPM synchronization signal across receive chains.

Although operations for particular operational or power modes are described in FIG. 6, the wireless receiver circuit 600 may perform additional or alternative operations in other power modes. For example, the wireless receiver circuit 600 may utilize components of a single auxiliary path in some low power modes. As another example, the wireless receiver circuit 600 may include a dedicated auxiliary mixer in some configuration and may utilize the dedicated auxiliary mixer in some low power modes (e.g., may not utilize any components of the primary path).

In FIG. 6, the LO cross route circuitry 630 enables additional paths (cross routes or cross routing) between component paths of different receive chains. In the example of FIG. 6, the LO cross route circuitry 630 provide additional paths between first and second receive chains of a LO generation circuit. Specifically, the LO cross route circuitry 630 provides paths between synchronization signal generation circuitry (e.g., LPM synchronization signal generators) of one chain to components (e.g., LPM or auxiliary components) of another chain.

Additionally, the LO cross route circuitry 630 enables additional paths (cross routes or cross routing) between component paths of a same receive chain, similar to FIG. 5. In the example of FIG. 6, the LO cross route circuitry 630 provide two alternative synchronization signals. Specifically, the LO cross route circuitry 630 provides alternative paths for synchronization signal generation circuitry (e.g., LPM synchronization signal generators) to provide synchronization signals to either primary or auxiliary components of the same chain. In the example of FIG. 6, LPM synchronization signals are provided to either a primary or auxiliary mixer buffer to reduce power. In other examples, the LO cross route circuitry 630 may provide additional paths between dividers and mixer buffers, dividers and mixers, signal generators and dividers, signal generations and mixers, or a combination thereof, as described further herein.

FIG. 7 is a circuit diagram illustrating a wireless receiver circuit 700 according to one or more aspects. In FIG. 7, two exemplary operational modes of the wireless receiver circuit 700 are illustrated, a first mode 702 (e.g., a high power mode) and a second mode 704 (e.g., a low power mode). The wireless receiver circuit 700 may include or correspond to a wireless receiver circuit for 5G NRU operations, such as operations in a 5G NR unlicensed spectrum and/or operations in LMH spectrum.

In some embodiments, the wireless receiver circuit 700 may be part of a sub-6 GHz radio frequency (RF) transceiver, a converged sub-6 Ghz and mmWave radio frequency (RF) transceiver, or a mmWave radio frequency (RF) transceiver. In some embodiments, portions of the RF receiver (or transceiver) of FIG. 7 may be located in a single integrated circuit (IC) sharing a common substrate, and each portion may be coupled to each other and to a PCB.

The wireless receiver circuit 700 includes a plurality of receive chains, where each receive chain includes multiple paths or component chains, such as main or high power mode paths, low power mode paths, auxiliary paths (e.g., harmonic rejection mixing paths), etc. One or more of the multiple paths or component chains may be used for different operational modes. Similar to FIGS. 5 and 6, the wireless receiver circuit 700 of FIG. 7 may be coupled to a baseband filter and an antenna and configured to receive RF signals and transmit RF signals. In FIG. 7, one receive chain is illustrated for simplicity.

Each receive chain of the wireless receiver circuit 700 may include synchronization signal generator circuitry configured to generate one or more types of synchronization signals or clock signals and provide the signals to the wireless receiver circuit, such as the dividers thereof. The synchronization signal generator circuitry may include or correspond to one or more synchronization signal generators, as described with reference to any of FIGS. 4-6. For example, each receive chain may include a single synchronization signal generator or multiple synchronization signal generators, such as high and low power mode synchronization signal generators. The synchronization signal generator circuitry of FIG. 7 may include or correspond to the receive frequency synthesizer 428, the transmit frequency synthesizer 438, or both, of FIG. 4, the synchronization signal generator 510 of FIG. 5, the synchronization signal generation circuitry 612 or 614 of FIG. 6, or a combination thereof.

The wireless receiver circuit 700 includes dividers 722 and 724, buffers 732-738, mixer buffers (e.g., two-stage mixer buffers of NAND gates 742, 744, and 746 and buffers 752, 754, and 756), and mixers 762, 764, 766. In FIG. 7, each receive chain includes a primary path 712 and one or more auxiliary paths 714. In the example of FIG. 7, the auxiliary paths 714 include a low power mode path and two harmonic rejection mixer paths.

The primary path 712 is associated with the divider 722, such as first or primary divider, and the harmonic rejection mixer path or paths are associated with the divider 724. Each path may have a corresponding mixer buffer and/or mixer. In the example of FIG. 7, the primary path (e.g., high power path) of the receive chain includes the divider 722, the buffer 734, a first or main mixer buffer (e.g., the NAND gate 742, the buffer 752), and the mixer 762. A first auxiliary path (e.g., upper harmonic rejection mixer path) of the receive chain includes the divider 724, the buffer 736, a first auxiliary mixer buffer (e.g., the NAND gate 744, the buffer 754), and the mixer 764. A second auxiliary path (e.g., lower harmonic rejection mixer path) of the receive chain includes the divider 724, the buffer 738, a second auxiliary mixer buffer (e.g., the NAND gate 746, the buffer 756), and the mixer 766. The first and second auxiliary paths may include or correspond to paths of a split HRM mixer buffer. A third auxiliary path (e.g., low power path) of the receive chain includes the mixer buffer 732 and one or more components of the first or second auxiliary paths (e.g., the NAND gates and onward). As compared to prior circuits which routed the LPM synchronization signal to the primary path and corresponding primary mixer buffer and mixer during LPM operations or modes, the LO cross route circuitry 730 (e.g., switches and traces) enables the wireless receiver circuit 700 to provide the LPM synchronization signal to other smaller and more power efficient auxiliary mixer buffers and/or auxiliary mixer during LPM operations or modes which reduces power consumption.

The wireless receiver circuit 700 may include many more receive chains and groups of receive chains. For example, in a particular implementation, the wireless receiver circuit 700 may include 8 groups of 8 receive chains for a total of 64 receive chains. Each group of receive chains may include or correspond to a separate chip or portion of chip which is implemented on a PCB.

In the example of FIG. 7, the LO cross route circuitry 730 of the wireless receiver circuit 700 is coupled to components downstream of the dividers and to components downstream of synchronization signal generation circuitry (and optionally independent of a divider). To illustrate, the LO cross route circuitry 730 may receive signals from a divider, such as divided synchronization signals or LO signals, and/or may receive signals from a synchronization signal generation circuitry, such as undivided synchronization signals or LO signals. The LO cross route circuitry 730 is configured to provide the received synchronization signals to one or more mixer buffers. In the example of FIG. 7, the LO cross route circuitry 730 is configured to provide the received synchronization signals to a main mixer buffer, auxiliary mixer buffers, or a combination thereof. Providing synchronization signals across paths or components chains may enable operations where a divider (e.g., a main divider, such as divider 722) is not powered down to reduce phase misalignment from powering off and on dividers.

The LO cross route circuitry 730 includes a plurality of paths, paths 770, configured to couple the received synchronization signals or LO signals to one or more of mixers, via the corresponding mixer buffer. For example, the LO cross route circuitry 730 provides the synchronization signal or LO signal via one or more paths of the paths 770 to mixer buffers of the primary path 712, the one or more auxiliary paths 714, or both. For example, the LO cross route circuitry 730 includes switches and traces to switch between providing the LO signal to the primary path, to the primary path and the two auxiliary paths, or to one or more of the auxiliary paths. To illustrate, the LO cross route circuitry 730 includes switches and traces to provide the LO signal from the divider 722 to any combination of mixer 762, mixer 764, or mixer 766.

These additional routing paths for the LO signal enable additional operational modes and power savings in the additional operational modes. For example, one or more auxiliary mixers may be used in a particular low power mode instead of using the main mixer. As the auxiliary mixers are generally smaller and have a lower power consumption, a power savings can be achieved by utilizing the additional paths from the LO cross route circuitry 730. As another example, in some implementations, the LO cross route circuitry 730 may selectively provide the LO signal to only a portion of the primary or auxiliary paths to reduce component usage and reduce power consumption. Similar to examples of FIG. 5, the LO cross route circuitry 730 may enable a particular divider, such as a main or shared divider (e.g., divider 522 of FIG. 5), to remain powered on during more or all operational modes to ensure phase alignment with other dividers and phase alignment between chains of the wireless receiver circuit 700, as described with reference to FIG. 5.

During high power mode operation, as illustrated in 702, the divider 722 receives a synchronization signal and reduces a frequency of the synchronization signal. The divider 722 outputs the reduced frequency synchronization signal to the buffer 734. In some implementations, a capacitor may be utilized before a buffer for signal processing and/or isolation as illustrated in FIG. 7. The buffer 734 processes the signal and provides the processed signal (LO signal) to the LO cross route circuitry 730. The LO cross route circuitry 730 provides the LO signal to the main or primary path. To illustrate, the LO cross route circuitry 730 provides the LO signal to the primary mixer buffer, NAND gate 742 and buffer 752. The primary mixer buffer, NAND gate 742 and buffer 752, process the LO signal and provide the LO signal to the mixer 762 (e.g., main or primary mixer).

Additionally, the divider 724 receives a synchronization signal (e.g., a same synchronization signal or a different synchronization signal) and reduces a frequency of the synchronization signal. The divider 724 outputs the reduced frequency synchronization signal to the buffer 736. In some implementations, a capacitor may be utilized before a buffer for signal processing and/or isolation. The buffer 734 processes the signal and provides the processed signal (LO signal) to the LO cross route circuitry 730. The LO cross route circuitry 730 provides the LO signal to the first and second auxiliary paths (e.g., first and second harmonic rejection mixer paths). To illustrate, the LO cross route circuitry 730 provides the LO signal to the auxiliary mixer buffers, NAND gate 744 and buffer 754 and NAND gate 746 and buffer 756. The auxiliary mixer buffers (e.g., harmonic rejection mixer buffers) process the LO signals and provide the LO signals to their corresponding auxiliary mixers, mixer 764 and mixer 766.

A RF signal is also provided to the mixer 762, such as from an antenna, and the mixer 762 (e.g., primary mixer or main mixer) processes the received signals (e.g., mixes the received signals) to generate an output signal (mixed signal or baseband signal). The output signal is provided to other circuitry for further processing, such as ADC and baseband processor circuitry. Additionally, the RF signal may also be provided to the auxiliary/harmonic rejection mixers, mixer 764 and mixer 766, such as from an antenna, and the mixers 764 and 766 (e.g., auxiliary mixer or harmonic rejection mixer) processes the received signals (e.g., mixes the received signals) to generate output signals (mixed signals or baseband signals). The output signals are provided to other circuitry for further processing, such as ADC and baseband processor circuitry.

During low power mode operation, as illustrated in 704, the divider 722 receives a synchronization signal and reduces a frequency of the synchronization signal. The divider 722 outputs the reduced frequency synchronization signal to the buffer 734. In some implementations, a capacitor may be utilized before a buffer for signal processing and/or isolation. The buffer 734 processes the signal and provides the processed signal (LO signal) to the LO cross route circuitry 730. The LO cross route circuitry 730 provides the LO signal to the first auxiliary path/first harmonic rejection mixer path. To illustrate, the LO cross route circuitry 730 provides the LO signal to the auxiliary mixer buffer, NAND gate 744 and buffer 754 and not the components of the second auxiliary path/second harmonic rejection mixer path. The auxiliary mixer buffer (e.g., harmonic rejection mixer buffer) processes the LO signal and provides the LO signal to the mixer 764. A RF signal is also provided to the mixer 764, such as from an antenna, and the mixer 764 (e.g., auxiliary mixer or harmonic rejection mixer) processes the received signals (e.g., mixes the received signals) to generate an output signal (mixed signal or baseband signal). The output signal is provided to other circuitry for further processing, such as ADC and baseband processor circuitry.

Although operations for particular operational or power modes are described in FIG. 7, the wireless receiver circuit 700 may perform additional or alternative operations in other power modes, such as the operations described in any of FIGS. 4-6. For example, the wireless receiver circuit 700 may utilize components of a single auxiliary path in some low power modes. As another example, the wireless receiver circuit 700 may include a single or dedicated primary path in some configurations and may utilize a single or dedicated primary mixer in some low power modes (e.g., may not utilize components (e.g., mixer and/or mixer buffers) of multiple primary paths).

In FIG. 7, the LO cross route circuitry 730 enables additional paths (cross routes or cross routing) between component paths of a single receive chain. In the example of FIG. 7, the LO cross route circuitry 730 provide additional paths between primary component paths and auxiliary component paths. Specifically, the LO cross route circuitry 730 provides paths for synchronization signals between dividers and/or synchronization signal generation circuitry and components of primary paths or components of auxiliary paths. In some implementations, the LO cross route circuitry 730 may include additional circuitry (e.g., switches and/or traces) to enable additional paths (cross routes or cross routing) between component paths of different receive chains, similar to FIG. 6.

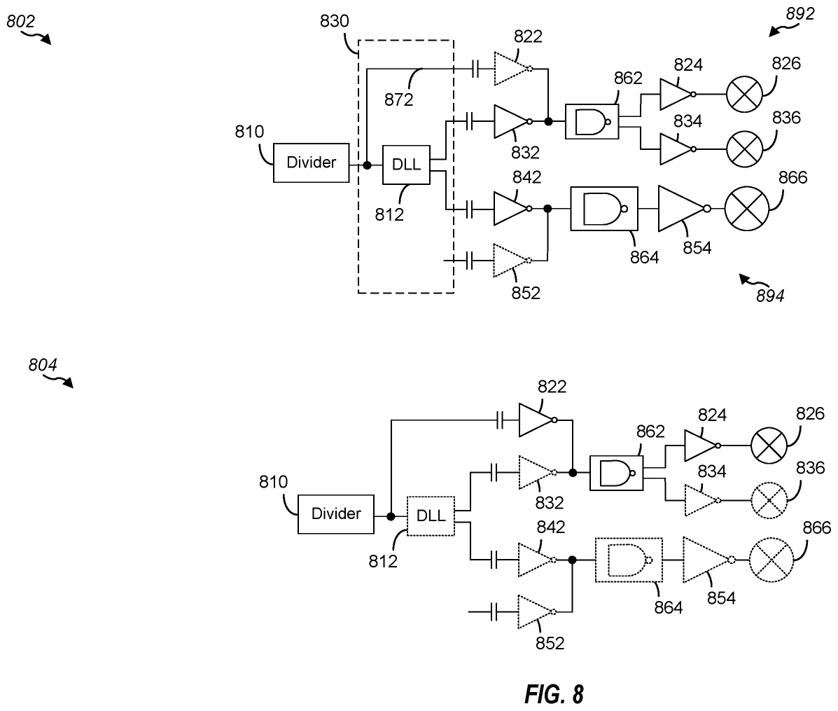

FIG. 8 is a circuit diagram illustrating a wireless receiver circuit 800 according to one or more aspects. In FIG. 8, two exemplary operational modes of the wireless receiver circuit 800 are illustrated, a first mode 802 (e.g., a high power mode or a high performance mode) and a second mode 804 (e.g., a low power mode or a low performance mode). The wireless receiver circuit 800 may include or correspond to a wireless receiver circuit for 5G C-Band operations.

In some embodiments, the wireless receiver circuit 800 may be part of a sub-6 GHz radio frequency (RF) transceiver, a converged sub-6 Ghz and mmWave radio frequency (RF) transceiver, or a mmWave radio frequency (RF) transceiver. In some embodiments, portions of the RF receiver (or transceiver) of FIG. 8 may be located in a single integrated circuit (IC) sharing a common substrate, and each portion may be coupled to each other and to a PCB.

The wireless receiver circuit 800 includes a plurality of receive chains, where each receive chain includes multiple paths or component chains, such as main or high power mode paths, low power mode paths, and auxiliary paths (e.g., harmonic rejection mixing paths). Similar to FIGS. 5-7, the wireless receiver circuit 800 of FIG. 8 may be coupled to a baseband filter and an antenna and configured to receive RF signals and transmit RF signals. In FIG. 8, one receive chain is illustrated for simplicity.

Each receive chain of the wireless receiver circuit 800 may include synchronization signal generator circuitry that includes one or more synchronization signal generators, as described with reference to any of FIGS. 4-6. For example, each receive chain may include a single synchronization signal generator or multiple synchronization signal generators, such as high and low power mode synchronization signal generators. The synchronization signal generator circuitry of FIG. 8 may include or correspond to the receive frequency synthesizer 428, the transmit frequency synthesizer 438, or both, of FIG. 4, the synchronization signal generator 510 of FIG. 5, the synchronization signal generation circuitry 612 or 614 of FIG. 6, or a combination thereof.

The wireless receiver circuit 800 includes a divider 810, a DLL 812, buffers 822, 832, 842, and 852, mixer buffers (including combinations of NAND gates 862 and 864 and buffers 824, 834, and 854), and mixers 826, 836, and 866. In the example of FIG. 8 each receive chain includes a primary path 894 and one or more auxiliary paths 892. The auxiliary paths include a low power mode path and two harmonic rejection mixer paths.

Multiple paths of the primary path 894 and the one or more auxiliary paths 892 are associated with the divider 810, such as a first or primary divider. Each path may have a mixer buffer and a mixer. In the example of FIG. 8, the primary path (e.g., high power path) of the receive chain includes the divider 810, the DLL 812, the buffer 842, the mixer buffer (e.g., the NAND gate 846 and the buffer 854), and the mixer 866. A first auxiliary path (e.g., upper harmonic rejection mixer path) of the receive chain includes the divider 810, the DLL 812, the buffer 832, harmonic rejection mixer buffer (e.g., the NAND gate 862 and the buffer 824), and the mixer 826. A second auxiliary path (e.g., lower harmonic rejection mixer path) of the receive chain includes the divider 810, the DLL 812, the buffer 832, harmonic rejection mixer buffer (e.g., the NAND gate 862 and the buffer 834), and the mixer 836. The first and second auxiliary paths may include or correspond to paths of a split HRM mixer buffer with a shared NAND gate and separate buffers coupled to a corresponding mixer.

A third auxiliary path (e.g., low power path) of the receive chain includes the divider 810, the buffer 822, the harmonic rejection mixer buffer(s) (e.g., the NAND gate 862 and the buffer(s) 824 and/or 834), and the mixer 826. A fourth auxiliary path (e.g., low power path) of the receive chain includes the buffer 852, the mixer buffer (e.g., the NAND gate 864 and the buffer 854), and the mixer 866. The fourth auxiliary path may receive a synchronization signal which is not divided or may receive a different synchronization signal, such as a second synchronization signal, from the synchronization signal received by the divider 810.

The wireless receiver circuit 800 may include many more receive chains and groups of receive chains. For example, in a particular implementation, the wireless receiver circuit 800 may include 8 groups of 8 receive chains for a total of 64 receive chains. Each group of receive chains may include or correspond to a separate chip or portion of chip which is implemented on a PCB.

In FIG. 8, the LO cross route circuitry 830 is configured to provide the received synchronization signal from the divider 810 to one or more mixer buffers via the DLL 812 and the buffers 822, 832, 842, and 852. In the example of FIG. 8, the LO cross route circuitry 830 is configured to provide the received synchronization signals from the divider 810 and/or synchronization signal generation circuitry to main or auxiliary mixer buffers of the receiver chain. The mixer buffers are connected to divider 810 and/or synchronization signal generation circuitry via LO cross route circuitry 830, and to mixers 826, 836, and 866.

The LO cross route circuitry 830 includes a plurality of cross-route paths, paths 872, configured to couple the output of the shared divider, divider 810, and/or the input the buffer 852 to components of one or more paths of the primary path 894 and the one or more auxiliary paths 892. In the example of FIG. 8, the LO cross route circuitry 830 selectively provides the received signals to buffers of the primary path 894, the one or more auxiliary paths 892, or a combination thereof. The outputs of the buffers of the different paths provide the LO signal to a corresponding mixer buffer and mixer associated with the respective path. For example, the LO cross route circuitry 830 provides the synchronization signal or LO signal received from the divider 810 to one or more primary and/or auxiliary paths.

The LO cross route circuitry 830 includes switches and traces to switch between outputting or providing the LO signal to the primary path 894, to the primary path and the one or more auxiliary paths 892, or to at least one path of the one or more auxiliary paths 892. To illustrate, the LO cross route circuitry 830 includes switches and traces to provide the LO signal to one or more buffers of the buffers 822, 832, or 842. When providing the LO signal to buffer 832 or buffer 842 the LO cross route circuitry 830 may provide the LO signal to the DLL 812 which provides the LO signal to the buffer 832, the buffer 842, or both via, respective capacitors. These additional routing paths for the LO signal enable additional operational modes and power savings in the additional operational modes. For example, one or more auxiliary mixers may be used in a particular low power mode instead of using the main mixer. As the auxiliary mixers are generally smaller and have a lower power consumption, a power savings can be achieved by utilizing the additional paths from the LO cross route circuitry 830. As another example, in some implementations, the LO cross route circuitry 830 may selectively provide the LO signal to only a portion of the auxiliary paths, such as only to auxiliary mixer buffer (buffer 824) or the auxiliary mixer buffer (buffer 834).

Similar to examples of FIG. 5 and FIG. 8, the LO cross route circuitry 830 may enable a particular divider, such as a main or shared divider (e.g., divider 522 or divider 810), to remain powered on during more or all operational modes to ensure phase alignment with other dividers and phase alignment between chains of the wireless receiver circuit 800, as described with reference to FIG. 5.

During high power mode operation, as illustrated in 802, the divider 810 receives a synchronization signal and reduces a frequency of the synchronization signal. The divider 810 outputs the reduced frequency synchronization signal to the DLL 812. The DLL 812 receives the reduced frequency synchronization signal and processes reduced frequency synchronization signal. The DLL 812 outputs the processed reduced frequency synchronization signal to the buffer 832 and to the buffer 842. In some implementations, a capacitor may be utilized before the buffers for signal processing and/or isolation. The buffers 832 and 842 process the signals and provide the processed signals (LO signals) to the corresponding mixer buffers and mixers their respective paths. To illustrate, the buffer 832 is part of the auxiliary path(s) (or harmonic rejection mixer paths) and provides an output signal to the auxiliary mixer buffers and mixers of the auxiliary path(s). The auxiliary mixer buffers, NAND gate 862 and buffers 824 and 834, each process the respective LO signal and provide their respective LO signal to their respective mixer, mixers 826 and 836 (e.g., auxiliary or harmonic rejection mixer). The buffer 842 is part of the primary path (high power or high performance mode path) and provides an output signal to the main or primary mixer buffers and mixers of the primary path. The primary or main mixer buffer, NAND gate 864 and buffer 854, each process the LO signal and provide the LO signal to the primary or main mixer, mixer 866.

A RF signal is also provided to the mixer 866, such as from an antenna, and the mixer 866 (e.g., main mixer or primary mixer) processes the received signals (e.g., mixes the received signals) to generate an output signal (mixed signal or baseband signal). The output signal is provided to other circuitry for further processing, such as ADC and baseband processor circuitry. Additionally, the RF signal is also provided to the auxiliary/harmonic rejection mixers, mixer 826 and mixer 836, such as from an antenna, and the mixers 826 and 836 (e.g., auxiliary mixer or harmonic rejection mixer) processes the received signals (e.g., mixes the received signals) to generate output signals (mixed signals or baseband signals). The output signals are provided to other circuitry for further processing, such as ADC and baseband processor circuitry.

During low power mode operation, as illustrated in 804, the divider 810 receives a synchronization signal and reduces a frequency of the synchronization signal. The divider 810 outputs the reduced frequency synchronization signal to the buffer 822. In some implementations, a capacitor may be utilized before a buffer for signal processing and/or isolation. The buffer 822 processes the signal and provides the LO signal to the auxiliary path or paths, such as the first harmonic rejection mixer path, the second harmonic rejection mixer path, or both. To illustrate, the buffer 822 provides the LO signal to the auxiliary rejection mixer buffer, NAND gate 862 and buffer 824 in the example of FIG. 8. The auxiliary rejection mixer buffer, NAND gate 862 and buffer 824, process the LO signal and provide the LO signal to the mixer 826. A RF signal is also provided to the mixer 826, such as from an antenna, and the mixer 826 (e.g., auxiliary mixer or harmonic rejection mixer) processes the received signals (e.g., mixes the received signals) to generate an output signal (mixed signal or baseband signal). The output signal is provided to other circuitry for further processing, such as ADC and baseband processor circuitry.

Although operations for particular operational or power modes are described in FIG. 8, the wireless receiver circuit 800 may perform additional or alternative operations in other power modes, such as the operations described in any of FIGS. 4-7. For example, the wireless receiver circuit 800 may utilize components of a single auxiliary path in some low power modes. As another example, the wireless receiver circuit 800 may include a single or dedicated primary path in some configurations and may utilize a single or dedicated primary mixer in some low power modes (e.g., may not utilize components (e.g., mixer and/or mixer buffers) of multiple primary paths).

In FIG. 8, the LO cross route circuitry 830 enables additional paths (cross routes or cross routing) between component paths of a single receive chain. In the example of FIG. 8, the LO cross route circuitry 830 provide additional paths between primary component paths and auxiliary component paths. Specifically, the LO cross route circuitry 830 provides paths for a shared synchronization signal between a shared divider (or shared synchronization signal generation circuitry (e.g., high power or performance mode (HPM) and/or low power or performance mode (LPM) synchronization signal generators) and components of primary paths or components of auxiliary paths. In some implementations, the LO cross route circuitry 830 may include additional circuitry (e.g., switches and/or traces) to enable additional paths (cross routes or cross routing) between component paths of different receive chains, similar to FIG. 6.

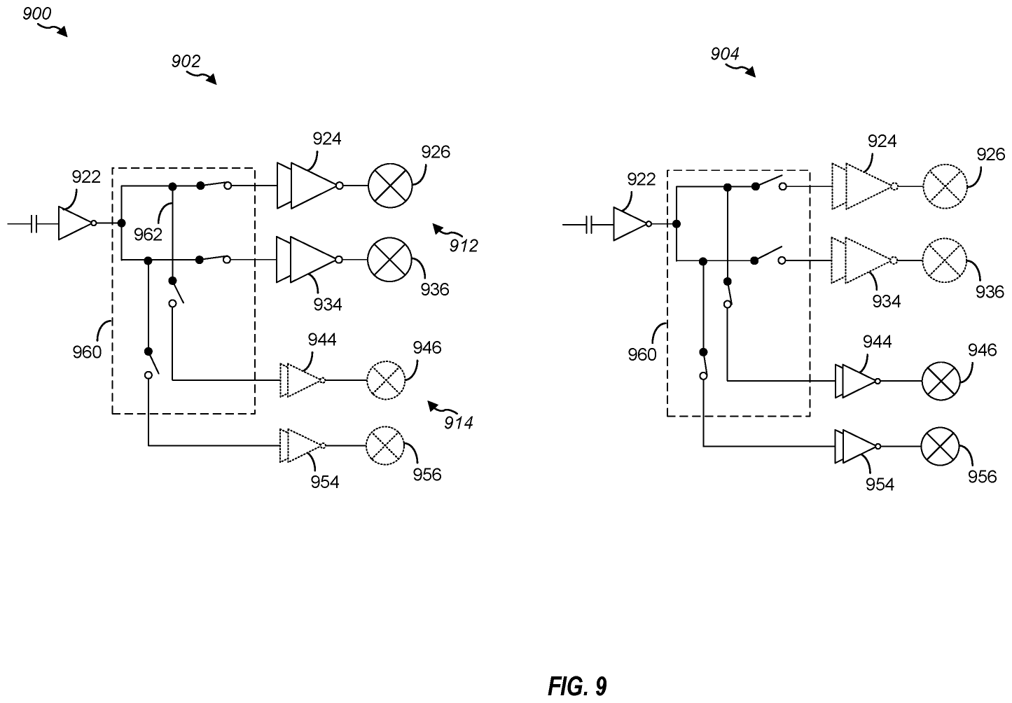

FIG. 9 is a circuit diagram illustrating a wireless receiver circuit 900 according to one or more aspects. In FIG. 9, two exemplary operational modes of the wireless receiver circuit 900 are illustrated, a first mode 902 (e.g., a high power mode or a high performance mode) and a second mode 904 (e.g., a low power mode or a low performance mode). The wireless receiver circuit 900 may include or correspond to a wireless receiver circuit for 5G NRU operations, such as operations in a 5G millimeter wave unlicensed spectrum.

In some embodiments, the wireless receiver circuit 900 may be part of a sub-6 GHz radio frequency (RF) transceiver, a converged sub-6 Ghz and mmWave radio frequency (RF) transceiver, or a mmWave radio frequency (RF) transceiver. In some embodiments, portions of the RF receiver (or transceiver) of FIG. 9 may be located in a single integrated circuit (IC) sharing a common substrate, and each portion may be coupled to each other and to a PCB.

The wireless receiver circuit 900 includes a plurality of receive chains, where each receive chain includes multiple paths or component chains, such as main or high power mode paths, low power mode paths, and auxiliary paths (e.g., harmonic rejection mixing paths). Similar to FIGS. 4-9, the wireless receiver circuit 900 of FIG. 9 may be coupled to a baseband filter and an antenna and configured to receive RF signals and transmit RF signals. In FIG. 9, one receive chain is illustrated for simplicity.

Each receive chain of the wireless receiver circuit 900 may include synchronization signal generator circuitry that includes one or more synchronization signal generators, as described with reference to any of FIGS. 4-6. For example, each receive chain may include a single synchronization signal generator or multiple synchronization signal generators, such as high and low power mode synchronization signal generators. The synchronization signal generator circuitry of FIG. 9 may include or correspond to the receive frequency synthesizer 428, the transmit frequency synthesizer 438, or both, of FIG. 4, the synchronization signal generator 510 of FIG. 5, the synchronization signal generation circuitry 612 or 614 of FIG. 6, or a combination thereof.

The wireless receiver circuit 900 may include one or more dividers, as illustrated in FIGS. 4-9, such as main and/or auxiliary dividers. Each divider may be associated with (e.g., configured to provide divided synchronization signals for) one or more chains and/or one or more paths of a particular chain, as described and illustrated with respect to FIGS. 5-8.

The wireless receiver circuit 900 includes a buffer 922 (e.g., a shared buffer), LO cross route circuitry 960, mixer buffers 924, 934, 944, and 954, and mixers 926, 936, 946, and 956. In the example of FIG. 9, each receive chain includes one or more primary paths 912 and one or more auxiliary paths 914. The auxiliary paths may include a low power mode path or paths and/or harmonic rejection mixer paths. The shared buffer, buffer 922, may be shared across multiple paths of the receive chain, and even across receive chains. In the example of FIG. 9, the buffer 922 is shared across the one or more primary paths 912 and the one or more auxiliary paths 914.

In the example of FIG. 9, each of the paths are associated with a mixer buffer and a mixer. In the example of FIG. 9, the primary paths (e.g., high power paths) of the receive chain include a first primary path of the buffer 922, the mixer buffer 924 (e.g., a two stage mixer buffer), and the mixer 926 and a second primary path of the buffer 922, the mixer buffer 934 (e.g., a two stage mixer buffer), and the mixer 936. A first auxiliary path (e.g., upper harmonic rejection mixer path) of the receive chain includes the buffer 922, the mixer buffer 944 (e.g., a two stage harmonic rejection mixer buffer), and the mixer 946. A second auxiliary path (e.g., lower harmonic rejection mixer path) of the receive chain includes the buffer 922, the mixer buffer 954 (e.g., a two stage harmonic rejection mixer buffer), and the mixer 956. The first and second auxiliary paths may include or correspond to paths of a split HRM mixer buffer with two paths. As illustrated in FIG. 9, the components of the one or more auxiliary paths 914 may be physically smaller and may have reduced power consumption as compared to the components of the one or more primary paths 912.

The wireless receiver circuit 900 may include many more receive chains and groups of receive chains. For example, in a particular implementation, the wireless receiver circuit 900 may include 8 groups of 8 receive chains for a total of 64 receive chains. Each group of receive chains may include or correspond to a separate chip or portion of chip which is implemented on a PCB.

In FIG. 9, each receive chain may include a shared divider for multiple paths of the receive chain. In the example of FIG. 9, the LO cross route circuitry 960 of the wireless receiver circuit 900 is coupled to the shared buffer, buffer 922. The LO cross route circuitry 960 is configured to provide the received synchronization signal from the buffer 922 to one or more mixer buffers. In the example of FIG. 9, the LO cross route circuitry 960 is configured to provide the received synchronization signals to main or auxiliary mixer buffers of the receiver chain. The mixer buffers are connected to the shared buffer, buffer 922, via LO cross route circuitry 960, and to mixers 926, 936, 946, and 956.

The LO cross route circuitry 960 includes a plurality of cross-route paths, paths 962, configured to couple the output of the buffer 922 to one or more of mixers, via the corresponding mixer buffer. For example, the LO cross route circuitry 960 selectively provides the synchronization signal or LO signal received for the receive chain and via the buffer 922 to components of the receive chain. To illustrate, LO cross route circuitry 960 is configurable to selectively provide received signals via one or more of the cross-routes, paths 962, to the one or more primary paths 912, the one or more auxiliary paths 914, or a combination thereof.

In the example of FIG. 9, the LO cross route circuitry 960 includes paths 962 between the shared buffer, buffer 922, to mixer buffers and mixers of each primary and auxiliary path. For example, the LO cross route circuitry 960 includes switches and traces to switch between outputting or providing the LO signal to two primary paths or to two auxiliary paths. To illustrate, the LO cross route circuitry 960 includes switches and traces to provide the LO signal to mixer buffers 924 and 934 or to provide the LO signal to mixer buffers 944 and 954. These additional routing paths for the LO signal enable additional operational modes and power savings in the additional operational modes. For example, one or more auxiliary mixers may be used in a particular low power mode instead of using the main mixer. As the auxiliary mixers are generally smaller and have a lower power consumption, a power savings can be achieved by utilizing the additional paths from the LO cross route circuitry 960. As another example, in some implementations, the LO cross route circuitry 960 may selectively provide the LO signal to only a portion of the primary or auxiliary paths, such as only to mixer buffer 924 or mixer buffer 934, or to only provide the LO signal to mixer buffer 944 or mixer buffer 954.

Similar to examples of FIG. 5 and FIG. 8, the LO cross route circuitry 960 may enable a particular divider, such as a main or shared divider (e.g., divider 522 of FIG. 5 or divider 89 of FIG. 8), to remain powered on during more or all operational modes to ensure phase alignment with other dividers and phase alignment between chains of the wireless receiver circuit 900, as described with reference to FIG. 5.

During high power mode operation, as illustrated in 902, the buffer 922 receives a synchronization signal (e.g., a divided or reduced frequency synchronization signal) and processes the synchronization signal. The buffer 922 outputs the processed frequency synchronization signal (LO signal) to the LO cross route circuitry 960. In some implementations, a capacitor may be utilized before a buffer for signal processing and/or isolation. The LO cross route circuitry 960 provides the LO signal to the primary path or paths, such as the first primary path, the second primary path, or both, of the one or more primary paths 912. To illustrate, the LO cross route circuitry 960 provides the LO signal to the mixer buffers of each primary path of the one or more primary paths 912. In the example of FIG. 9, the LO cross route circuitry 960 provides the LO signal to the mixer buffer 924 (e.g., first two-stage primary mixer buffer) and to the mixer buffer 934 (e.g., second two-stage primary mixer buffer). The mixer buffers 924 and 934 process their respective received LO signals and provide their respective processed or output LO signals to corresponding mixers, mixer 926 and mixer 936 respectively. A received RF signal may also be provided to mixer 926 and to mixer 936, such as from an antenna, and the mixers 926 and 936 (e.g., primary mixers or high power mode mixers) process the received signals (e.g., mixes the received signals) to generate a corresponding output signal (mixed signal or baseband signal). The output signals are provided to other circuitry for further processing, such as ADC and baseband processor circuitry.

During low power mode operation, as illustrated in 904, the buffer 922 receives a synchronization signal (e.g., a divided or reduced frequency synchronization signal) and processes the synchronization signal. The buffer 922 outputs the processed frequency synchronization signal (LO signal) to the LO cross route circuitry 960. In some implementations, a capacitor may be utilized before a buffer for signal processing and/or isolation. The LO cross route circuitry 960 provides the LO signal to the auxiliary path or paths, such as the first harmonic rejection mixer path, the second harmonic rejection mixer path, or both, of the one or more auxiliary paths 914. To illustrate, the LO cross route circuitry 960 provides the LO signal to the auxiliary mixer buffers of each auxiliary path of the one or more auxiliary paths 914. In the example of FIG. 9, the LO cross route circuitry 960 provides the LO signal to the mixer buffer 944 (e.g., first two-stage harmonic rejection mixer buffer) and provides the LO signal to the mixer buffer 954 (e.g., second two-stage harmonic rejection mixer buffer). The mixer buffers 944 and 954 process their respective LO signals and provide their respective LO signals to corresponding mixers, mixer 946 and mixer 956 respectively. A RF signal may also be provided to mixer 946 and to mixer 956, such as from an antenna, and the mixers 946 and 956 (e.g., auxiliary mixer or harmonic rejection mixers) process the received signals (e.g., mixes the received signals) to generate a corresponding output signal (mixed signal or baseband signal). The output signals are provided to other circuitry for further processing, such as ADC and baseband processor circuitry.

Although operations for particular operational or power modes are described in FIG. 9, the wireless receiver circuit 900 may perform additional or alternative operations in other power modes, such as the operations described in any of FIGS. 4-8. For example, the wireless receiver circuit 900 may utilize components of a single auxiliary path in some low power modes. As another example, the wireless receiver circuit 900 may include a single or dedicated primary path in some configurations and may utilize a single or dedicated primary mixer in some low power modes (e.g., may not utilize components (e.g., mixer and/or mixer buffers) of multiple primary paths).

In FIG. 9, the LO cross route circuitry 960 enables additional paths (cross routes or cross routing) between component paths of a single receive chain. In the example of FIG. 9, the LO cross route circuitry 960 provide additional paths between primary component paths and auxiliary component paths. Specifically, the LO cross route circuitry 960 provides paths between a buffer or synchronization signal generation circuitry (e.g., HPM and/or LPM synchronization signal generators) for a shared synchronization signal and components of primary paths or components of auxiliary paths. In some implementations, the LO cross route circuitry 960 may include additional circuitry (e.g., switches and/or traces) to enable additional paths (cross routes or cross routing) between component paths of different receive chains, similar to FIG. 6.

Although FIGS. 5-9 illustrate receive chains and receive operations, the aspects described herein are applicable to feedback receive chains and transmitter chains and accordingly feedback receive operations and transmit operations. For example, wireless transmitter or transceiver circuits may also include LO cross route circuitry as described herein and may be utilized to reduce power consumption for feedback receive and/or transmit operations and for transmit and/or feedback receive calibration operations.

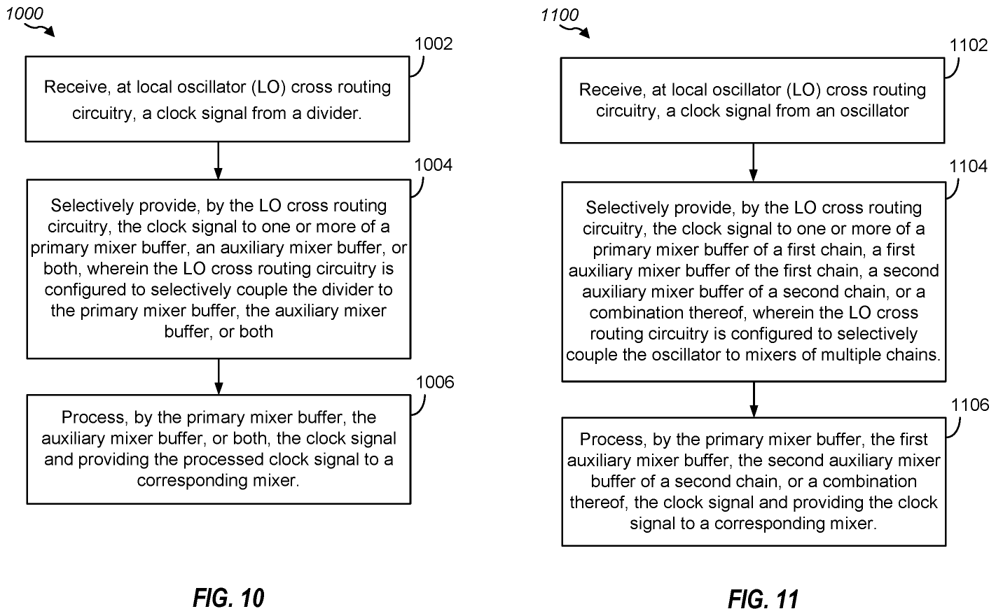

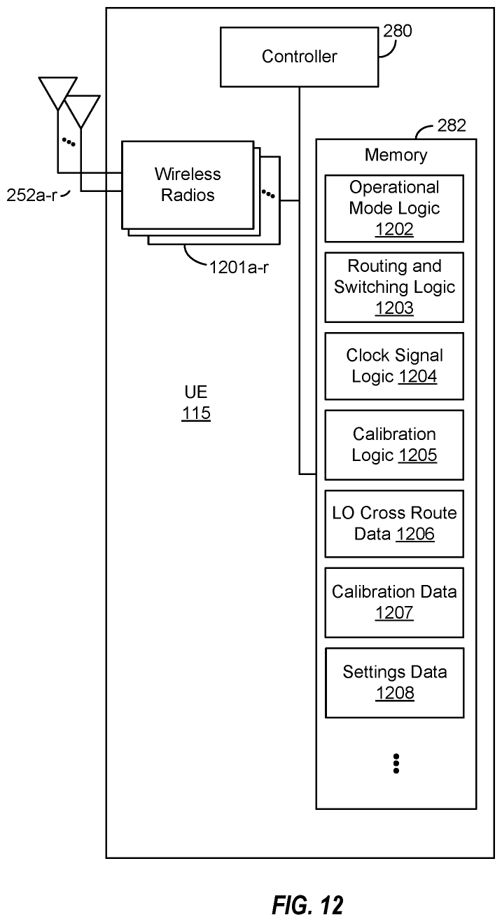

FIG. 10 is a flow diagram 1000 illustrating example blocks executed by a wireless communication device (e.g., a UE or base station) configured according to an aspect of the present disclosure. The example blocks will also be described with respect to UE 115 as illustrated in FIG. 12. FIG. 12 is a block diagram illustrating UE 115 configured according to one aspect of the present disclosure. UE 115 includes the structure, hardware, and components as illustrated for UE 115 of FIGS. 2-9. For example, UE 115 includes controller/processor 280, which operates to execute logic or computer instructions stored in memory 282, as well as controlling the components of UE 115 that provide the features and functionality of UE 115. UE 115, under control of controller/processor 280, transmits and receives signals via wireless radios 1201a-r and antennas 252a-r. Wireless radios 1201a-r includes various components and hardware, as illustrated in FIG. 2 for UE 115, including modulator/demodulators 254a-r, MIMO detector 256, receive processor 258, transmit processor 264, and TX MIMO processor 266. As illustrated in the example of FIG. 12, memory 282 stores operational mode logic 1202, routing and switching logic 1203, clock signal logic 1204, calibration logic 1205, LO cross route data 1206, calibration data 1207, and settings data 1208. The data (1202-1208) stored in the memory 282 may include or correspond to data and/or logic to enable the operations of FIGS. 4-9.

At block 1002, a wireless communication device, such as a UE or a base station, receives, at local oscillator (LO) cross routing circuitry, a clock signal from a divider. The clock signal may include or correspond to a clock signal, oscillation signal, or synchronization signal as described with reference to FIGS. 4-9. The clock signal may be generated by a frequency synthesizer or an oscillator of synchronization signal generator circuitry. The LO cross routing circuitry may include or correspond to LO cross routing circuitry as described with reference to FIGS. 4-9, such as LO generation circuitry 426 or 436 of FIG. 4, LO cross routing circuitry 530 of FIG. 5, LO cross routing circuitry 630 of FIG. 6, LO cross routing circuitry 730 of FIG. 7, LO cross routing circuitry 830 of FIG. 8, or LO cross routing circuitry 960 of FIG. 9. The divider may include or correspond to a fixed or configurable divider and/or a primary or auxiliary divider as described with reference to FIGS. 4-9, such as any of dividers of the LO generation circuitry 426 or 436 of FIG. 4, dividers 522 or 524 of FIG. 5, dividers 642 or 644 of FIG. 6, dividers 722 or 724 of FIG. 7, or divider 810 of FIG. 8. As one illustrative example, the LO cross routing circuitry 530 receives a synchronization signal generated by the synchronization signal generator 510 from the divider 522, as described with reference to FIG. 5. Many other examples are described in FIGS. 4-9.

At block 1004, the wireless communication device processes, by each receive chain, the selectively providing, by the LO cross routing circuitry, the clock signal to one or more of a primary mixer buffer, an auxiliary mixer buffer, or both, wherein the LO cross routing circuitry is configured to selectively couple the divider to the primary mixer buffer, the auxiliary mixer buffer, or both. The primary mixer buffer may include or correspond to a primary mixer buffer, single or multiple stage, as described with reference to FIGS. 4-9, such as any of primary mixer buffers of the LO generation circuitry 426 or 436 of FIG. 4, mixer buffer 542 of FIG. 5, mixer buffers 652 and 654 of FIG. 6, main mixer buffer (e.g., NAND gate 742 and buffer 752) of FIG. 7, mixer buffer (e.g., NAND gate 864 and buffer 854) of FIG. 8, or mixer buffers 924 or 934 of FIG. 9. The auxiliary mixer buffer may include or correspond to an auxiliary or HRM mixer buffer, single or multiple stage, as described with reference to FIGS. 4-9, such as any of auxiliary or HRM mixer buffers of the LO generation circuitry 426 or 436 of FIG. 4, mixer buffers 544 or 546 of FIG. 5, auxiliary mixer buffers (e.g., NAND gates 744 or 746 and buffers 754 or 756) of FIG. 7, mixer buffers (e.g., NAND gate 862 and buffers 824 or 834) of FIG. 8, or mixer buffers 944 or 954 of FIG. 9. For example, the LO cross routing circuitry 530 configures one or more switches or traces or deliver power to particular components to provide the received synchronization signal along one or more paths 532 of the LO cross routing circuitry 530 to selectively output the synchronization signal to the mixer buffer 542 of the primary path 502, to the mixer buffer or buffers 554 or 556 of one or more of the auxiliary paths 504, or a combination thereof, as described with reference to FIG. 5. Many other examples are described in FIGS. 4-9.

At block 1006, the wireless communication device processing, by the primary mixer buffer, the auxiliary mixer buffer, or both, the clock signal and providing the processed clock signal to a corresponding mixer. The processed clock signal may include or correspond to a LO signal, as described with reference to FIGS. 4-9, such as a signal output by a mixer buffer and input into a mixer. The mixer may include or correspond to a primary or auxiliary mixer as described with reference to FIGS. 4-9, such as any of mixers 424 or 434 of FIG. 4, mixers 552, 554 or 556 of FIG. 5, mixers 662 or 664 of FIG. 6, mixers 762-766 of FIG. 7, or mixers 826, 836, or 866 of FIG. 8, or mixers 926-956 of FIG. 9. As one illustrative example, the mixer buffer 544 receives the synchronization signal, processes the synchronization signal to generate an LO signal, and provides the LO signal to the mixer 554, as described with reference to FIG. 5. Many other examples are described in FIGS. 4-9.

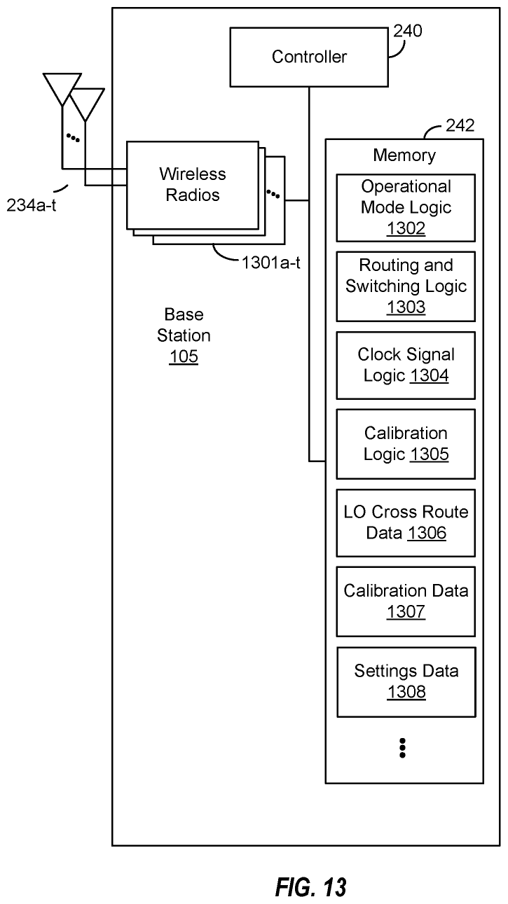

Although the operations of FIG. 10 were described with reference to UE 115 of FIG. 12, the operations of FIG. 10 may be performed by other wireless communication devices, such as network device (e.g., base station 105 of FIG. 13). The wireless communication device (e.g., UE or base station) may execute additional blocks (or the wireless communication device may be configured further perform additional operations) in other implementations. For example, the wireless communication device may perform one or more operations described above, such as described with reference to FIGS. 4-9. As another example, the wireless communication device may perform one or more aspects as presented below.

Accordingly, wireless communication devices may be able to more efficiently perform reception and transmission operations by utilizing the LO cross route circuitry of the LO generation circuitry. Improved efficiency through enhanced and configurable selection of components reduces overall power consumption and enables longer battery life. Accordingly, the device performance and experience may be increased due to the reduction in power usage.

FIG. 11 is a flow diagram 1100 illustrating example blocks executed wireless communication device (e.g., a UE or a network entity, such as a base station) configured according to an aspect of the present disclosure. The example blocks will also be described with respect to base station 105 as illustrated in FIG. 13. FIG. 13 is a block diagram illustrating base station 105 configured according to one aspect of the present disclosure. Base station 105 includes the structure, hardware, and components as illustrated for base station 105 of any of FIGS. 2-9. For example, base station 105 includes controller/processor 240, which operates to execute logic or computer instructions stored in memory 242, as well as controlling the components of base station 105 that provide the features and functionality of base station 105. Base station 105, under control of controller/processor 240, transmits and receives signals via wireless radios 1301a-t and antennas 234a-t. Wireless radios 1301a-t includes various components and hardware, as illustrated in FIG. 2 for base station 105, including modulator/demodulators 232a-t, MIMO detector 236, receive processor 238, transmit processor 220, and TX MIMO processor 230. As illustrated in the example of FIG. 13, memory 242 stores operational mode logic 1302, routing and switching logic 1303, clock signal logic 1304, calibration logic 1305, LO cross route data 1306, calibration data 1307, and settings data 1308. The data (1302-1308) stored in the memory 242 may include or correspond to data and/or logic to enable the operations of FIGS. 4-9.

At block 1102, a wireless communication device, such as a UE or a network device (e.g., a base station 105), receives, at local oscillator (LO) cross routing circuitry, a clock signal from an oscillator. The clock signal may include or correspond to a clock signal, oscillation signal, or synchronization signal as described with reference to FIGS. 4-9. The LO cross routing circuitry may include or correspond to LO cross routing circuitry as described with reference to FIGS. 4-9, such as LO generation circuitry 426 or 436 of FIG. 4, LO cross routing circuitry 530 of FIG. 5, LO cross routing circuitry 630 of FIG. 6, LO cross routing circuitry 730 of FIG. 7, LO cross routing circuitry 830 of FIG. 8, or LO cross routing circuitry 960 of FIG. 9. The oscillator may include or correspond to synchronization signal generation circuitry as described with reference to FIGS. 4-9, such as any of frequency synthesizers 428 or 438 of FIG. 4, synchronization signal generator 510 of FIG. 5, or synchronization signal generation circuitry 612 or 614 (e.g., 622, 624, 632, or 634 thereof) of FIG. 6. As one illustrative example, the LO cross routing circuitry 630 receives a synchronization signal generated by the synchronization signal generator 624 from the synchronization signal generation circuitry 612, as described with reference to FIG. 6. Many other examples are described in FIGS. 4-9.

At block 1104, the wireless communication device selectively provides, by the LO cross routing circuitry, the clock signal to one or more of a primary mixer buffer of a first chain, a first auxiliary mixer buffer of the first chain, a second auxiliary mixer buffer of a second chain, or a combination thereof, wherein the LO cross routing circuitry is configured to selectively couple the oscillator to mixers of multiple chains. The primary mixer buffer may include or correspond to a primary mixer buffer, single or multiple stage, as described with reference to FIGS. 4-9, such as any of primary mixer buffers of the LO generation circuitry 426 or 436 of FIG. 4, mixer buffer 542 of FIG. 5, mixer buffers 652 and 654 of FIG. 6, main mixer buffer (e.g., NAND gate 742 and buffer 752) of FIG. 7, mixer buffer (e.g., NAND gate 864 and buffer 854) of FIG. 8, or mixer buffers 924 or 934 of FIG. 9. The auxiliary mixer buffer may include or correspond to an auxiliary or HRM mixer buffer, single or multiple stage, as described with reference to FIGS. 4-9, such as any of auxiliary or HRM mixer buffers of the LO generation circuitry 426 or 436 of FIG. 4, mixer buffers 544 or 546 of FIG. 5, auxiliary mixer buffers (e.g., NAND gates 744 or 746 and buffers 754 or 756) of FIG. 7, mixer buffers (e.g., NAND gate 862 and buffers 824 or 834) of FIG. 8, or mixer buffers 944 or 954 of FIG. 9. The first and second chain may include or corresponds to one or more primary or auxiliary chains and/or one or more transmit or receive chains as described with reference to FIGS. 4-9, such as first receive chain 602 and second receive chain 604 of FIG. 6. For example, the LO cross routing circuitry 630 configures one or more switches or traces or delivers power to particular components to provide the received synchronization signal along one or more paths 631 of the LO cross routing circuitry 630 to selectively output the synchronization signal to the mixer buffer 652 or the mixer buffer 654 of the first receive chain 602, the mixer buffer 656 of the second receive chain 604, or a combination thereof, as described with reference to FIG. 6. Many other examples are described in FIGS. 4-9.

At block 1106, the wireless communication device processes, by the primary mixer buffer, the first auxiliary mixer buffer, the second auxiliary mixer buffer of a second chain, or a combination thereof, the clock signal and provides the clock signal to a corresponding mixer. The processed clock signal may include or correspond to a LO signal, as described with reference to FIGS. 4-9, such as a signal output by a mixer buffer and input into a mixer. The mixer may include or correspond to a primary or auxiliary mixer as described with reference to FIGS. 4-9, such as any of mixers 424 or 434 of FIG. 4, mixers 552, 554 or 556 of FIG. 5, mixers 662 or 664 of FIG. 6, mixers 762-766 of FIG. 7, or mixers 826, 836, or 866 of FIG. 8, or mixers 926-956 of FIG. 9. As one illustrative example, the mixer buffer 656 receives the synchronization signal, processes the synchronization signal to generate an LO signal, and provides the LO signal to the mixer 664 of the second receive chain 604, as described with reference to FIG. 6. Many other examples are described in FIGS. 4-9.

Although the operations of FIG. 11 were described with reference to base station 105 of FIG. 13, the operations of FIG. 11 may be performed by other wireless communication devices, such as UE 115 of FIG. 12. The wireless communication device (e.g., such as a UE or base station) may execute additional blocks (or the wireless communication device may be configured further perform additional operations) in other implementations. For example, the wireless communication device may perform one or more operations as described with reference to FIGS. 4-10. As another example, the wireless communication device may perform one or more aspects as presented below.

Accordingly, wireless communication devices may be able to more efficiently perform reception and transmission operations by utilizing the LO cross route circuitry of the LO generation circuitry. Improved efficiency through enhanced and configurable selection of components reduces overall power consumption and enables longer battery life. Accordingly, the device performance and experience may be increased due to the reduction in power usage.

In a first aspect, a transceiver system includes: one or more receive chains; and one or more transmit chains, wherein a receive chain of the one or more receive chains or a transmit chain of the one or more transmit chains includes: one or more dividers one or more dividers configured to receive a clock signal; local oscillator (LO) cross routing circuitry coupled to the one or more dividers; a mixer coupled to the LO cross routing circuitry; and one or more auxiliary mixers coupled to the LO cross routing circuitry, wherein the LO cross routing circuitry is configured to selectively couple a particular divider of the one or more dividers to the mixer, to at least one auxiliary mixer of the one or more auxiliary mixers, or any combination thereof.

In a second aspect, alone or in combination with the first aspect, the LO cross routing circuitry comprises one or more traces and optionally one or more switches, and the LO cross routing circuitry provides a plurality of selectable paths from the particular divider for providing the clock signal to the mixer, the least one auxiliary mixer, or both.

In a third aspect, alone or in combination with one or more of the above aspects, the receive chain or the transmit chain includes: a harmonic rejection mixer including the mixer and at least one auxiliary mixer of the one or more auxiliary mixers. In some such aspects, at least one auxiliary mixer of the one or more auxiliary mixers is smaller in area than the mixer.

In a fourth aspect, alone or in combination with one or more of the above aspects, the one or more dividers include a primary divider and an auxiliary divider, and the LO cross routing circuitry is further configured to selectively couple the primary divider of the one or more dividers to the mixer and to at least one auxiliary mixer of the one or more auxiliary mixers.

In a fifth aspect, alone or in combination with one or more of the above aspects, the primary divider has a fixed divide ratio or a configurable divide ratio, and the auxiliary divider has a configurable divide ratio.

In a sixth aspect, alone or in combination with one or more of the above aspects, the LO cross routing circuitry is further configured to selectively couple the auxiliary divider of the one or more dividers to the mixer and to at least one auxiliary mixer of the one or more auxiliary mixers.

In a seventh aspect, alone or in combination with one or more of the above aspects, the transceiver system further includes: a first oscillator coupled to the one or more dividers and configured to generate the clock signal; and a second oscillator coupled to the one or more dividers, wherein the first oscillator corresponds to a primary or high power mode oscillator, wherein the first second oscillator corresponds to a secondary or low power mode oscillator, and wherein the second oscillator has second type different from a first type of the first oscillator.

In an eighth aspect, alone or in combination with one or more of the above aspects, the transceiver system further includes: an antenna, and a low noise amplifier coupled to the antenna and the mixers; or a power amplifier coupled to the antenna and the mixers.

In a ninth aspect, alone or in combination with one or more of the above aspects, the mixer is a primary mixer and the one or more auxiliary mixers include two or more auxiliary mixers, and the transceiver system further includes: a second primary mixer, wherein the two or more auxiliary mixers are each smaller than the primary mixers, consume less power, or both.

In a tenth aspect, alone or in combination with one or more of the above aspects, the transceiver system further includes an oscillator coupled to the one or more dividers and configured to generate the clock signal, and the oscillator comprises a phase-locked loop (PLL), a voltage-controlled oscillator (VCO), a ring-VCO (RVCO), or an inductance-capacitance VCO (LCVCO).

In an eleventh aspect, alone or in combination with one or more of the above aspects, the one or more dividers include a primary divider and an auxiliary divider, wherein the LO cross routing circuitry is coupled to the primary divider and the auxiliary divider, and the transceiver system further includes: a primary mixer buffer coupled to the LO cross routing circuitry and to the mixer; and one or more auxiliary mixer buffers coupled to the LO cross routing circuitry and to a respective auxiliary mixer of the one or more auxiliary mixers, wherein the LO cross routing circuitry is configurable to provide signals from the primary divider to the mixer via the primary mixer buffer or to at least one auxiliary mixer of the one or more auxiliary mixers via a corresponding auxiliary mixer buffer of the one or more auxiliary mixer buffers.

In a twelfth aspect, alone or in combination with one or more of the above aspects, the one or more dividers includes a single, shared divider, and the transceiver system further includes: a delay-locked loop (DLL) coupled to the single, shared divider and coupled to the one or more auxiliary mixers via at least one or more auxiliary mixer buffers and coupled to the mixer via at least a mixer buffer.

In a thirteenth aspect, alone or in combination with one or more of the above aspects, the one or more auxiliary mixer buffers comprises a shared auxiliary mixer buffer for two or more auxiliary paths.

In a fourteenth aspect, alone or in combination with one or more of the above aspects, the shared auxiliary mixer buffer includes a shared not-and (NAND) gate for multiple auxiliary paths of the two or more auxiliary paths and a buffer for each path of the multiple auxiliary paths.

In a fifteenth aspect, alone or in combination with one or more of the above aspects, the LO cross routing circuitry is coupled to the particular divider via a buffer and comprises a plurality of traces and a plurality of switches, and wherein the plurality of traces and the plurality of switches are configured to selectively provide an output of the buffer to two primary paths or to two auxiliary paths.

In a sixteenth aspect, alone or in combination with one or more of the above aspects, the LO cross routing circuitry is configured to selectively couple the particular divider of the one or more dividers to the mixer via corresponding mixer buffer and to at least one auxiliary mixer of the one or more auxiliary mixers via a corresponding auxiliary mixer buffer, and wherein the mixer buffer comprises a two-stage mixer buffer or a single-tone generator buffer.

In a seventeenth aspect, alone or in combination with one or more of the above aspects, the LO cross routing circuitry is configured to selectively couple the particular divider of the one or more dividers to the mixer via corresponding mixer buffer and to at least one auxiliary mixer of the one or more auxiliary mixers via a corresponding auxiliary mixer buffer, and wherein the mixer buffer comprises a not-and (NAND) gate and a buffer.

In an eighteenth aspect, a method for wireless communication includes: receiving, at local oscillator (LO) cross routing circuitry, a clock signal from a divider; selectively providing, by the LO cross routing circuitry, the clock signal to one or more of a primary mixer buffer, an auxiliary mixer buffer, or both, wherein the LO cross routing circuitry is configured to selectively couple the divider to the primary mixer buffer, the auxiliary mixer buffer, or both; and processing, by the primary mixer buffer, the auxiliary mixer buffer, or both, the clock signal and providing the processed clock signal to a corresponding mixer.

In a nineteenth aspect, alone or in combination with the eighteenth aspect, where during a low power mode or low performance mode operation: the LO cross routing circuitry selectively provides the clock signal from the divider to the auxiliary mixer buffer; and the auxiliary mixer buffer processes the clock signal provides the processed clock signal to a first auxiliary mixer, and further comprising: receiving, at the first auxiliary mixer, the processed clock signal and an RF input from an antenna; and outputting, by the first auxiliary mixer, a mixed signal based on the processed clock signal and the RF input.

In a twentieth aspect, alone or in combination with the eighteenth or nineteenth aspects, the divider is a primary divider, and wherein during a low power mode or low performance mode operation the LO cross routing circuitry selectively provides the clock signal from the divider to auxiliary mixer buffer, and the method further includes: powering off an auxiliary divider associated with the primary divider.

In a twenty-first aspect, a transceiver system includes: a first oscillator; a second oscillator; local oscillator (LO) cross routing circuitry coupled to the first and second oscillators; a first mixer coupled to the LO cross routing circuitry; and a second mixer coupled to the LO cross routing circuitry, where the LO cross routing circuitry is configured to selectively couple at least one of the first oscillator or the second oscillator to the first mixer or to the second mixer via a corresponding auxiliary mixer buffer, and where the first oscillator and the first mixer are part of a first transmit or receive chain and the second oscillator and the second mixer are part of a second transmit or receive chain.

In a twenty-second aspect, alone or in combination with the twenty-first aspect, the LO cross routing circuitry comprises one or more traces and optionally one or more switches, and the first oscillator and the second oscillator each comprise a first type of oscillator for a low power mode, and the transceiver system further includes: third and fourth oscillators, where the third oscillator and the fourth oscillator each comprise a second type of oscillator for a high power mode; first and second dividers, the first divider coupled to the third oscillator, the second divider coupled to the fourth oscillator, first and second main mixer buffers, the first main mixer buffer coupled to the first divider and the first mixer, the second main mixer buffer coupled to the second divider and the second mixer; and first and second auxiliary mixer buffers, the first auxiliary mixer buffer coupled to the LO cross routing circuitry and the first mixer, the second auxiliary mixer buffer coupled to the LO cross routing circuitry and the second mixer, where the LO cross routing circuitry is configured to selectively couple the first oscillator to the first mixer via the first main mixer buffer or the first auxiliary mixer buffer, and where the third oscillator and the first divider are part of the first transmit or receive chain and the fourth oscillator and the second divider are part of the second transmit or receive chain.

In a twenty-third aspect, alone or in combination with the twenty-first or twenty-second aspects, the first and third oscillators are included in first phase-locked loop (PLL) circuitry, and wherein the second and fourth oscillators are included in second PLL circuitry.

In a twenty-fourth aspect, alone or in combination with the twenty-first through twenty-third aspects, the first and second oscillators comprise a voltage-controlled oscillator (VCO), and the third and fourth oscillators comprises a ring VCO (RVCO).

In a twenty-fifth aspect, alone or in combination with the twenty-first through twenty-fourth aspects, the transceiver system further comprises: an antenna, and a low noise amplifier coupled to the antenna and the mixers; or a power amplifier coupled to the antenna and the mixers.

In a twenty-sixth aspect, alone or in combination with the twenty-first through twenty-fifth aspects, the first mixer and the second mixer each comprise auxiliary mixers, the LO cross routing circuitry comprises one or more traces and optionally one or more switches, and the first oscillator and the second oscillator each comprise a first type of oscillator for a low power mode, and the transceiver system further comprises: third and fourth oscillators, where the third oscillator and the fourth oscillator each comprise a second type of oscillator for a high power mode; first and second dividers, the first divider coupled to the third oscillator, the second divider coupled to the fourth oscillator, first and second main mixer buffers, the first main mixer buffer coupled to the LO cross routing circuitry, the first divider, and a first main mixer, the second main mixer buffer coupled to the LO cross routing circuitry, the second divider, and a second main mixer; first and second auxiliary mixer buffers, the first auxiliary mixer buffer coupled to the LO cross routing circuitry and the first auxiliary mixer, the second auxiliary mixer buffer coupled to the LO cross routing circuitry and the second auxiliary mixer; and where the LO cross routing circuitry is configured to selectively couple the first oscillator to the first mixer via the first main mixer buffer, to the first auxiliary mixer via the first auxiliary mixer buffer, or to the second auxiliary mixer via the second auxiliary mixer buffer.

In a twenty-seventh aspect, a method for wireless communication includes: receiving, at local oscillator (LO) cross routing circuitry, a clock signal from an oscillator; selectively providing, by the LO cross routing circuitry, the clock signal to one or more of a primary mixer buffer of a first chain, a first auxiliary mixer buffer of the first chain, a second auxiliary mixer buffer of a second chain, or a combination thereof, wherein the LO cross routing circuitry is configured to selectively couple the oscillator to mixers of multiple chains; and processing, by the primary mixer buffer, the first auxiliary mixer buffer, the second auxiliary mixer buffer of a second chain, or a combination thereof, the clock signal and providing the clock signal to a corresponding mixer.

In a twenty-eight aspect, alone or in combination with the twenty-seventh aspect, the method further comprises: receiving, at the LO cross routing circuitry from a second oscillator, a second clock signal; selectively providing, by the LO cross routing circuitry, the second clock signal to one or more of a second primary mixer buffer of the second chain, the first auxiliary mixer buffer of the first chain, the second auxiliary mixer buffer of the second chain, or a combination thereof, wherein the LO cross routing circuitry is configured to selectively couple the second oscillator to mixers of multiple chains; and processing, by the second primary mixer buffer, the first auxiliary mixer buffer, the second auxiliary mixer buffer, or a combination thereof, the second clock signal and providing the second clock signal to a corresponding mixer.

In a twenty-ninth aspect, alone or in combination with the twenty-seventh or twenty-eighth aspects, where during a residual sideband (RSB) calibration operation: the LO cross routing circuitry selectively provides: the clock signal from the oscillator of the first chain to the second auxiliary mixer buffer of the second chain; and the second clock signal from the second oscillator of the second chain to the first auxiliary mixer buffer of the first chain; the first auxiliary mixer buffer provides the second clock signal to a first mixer of the first chain; and the second auxiliary mixer buffer provides the clock signal to a second mixer of the second chain.

In a thirtieth aspect, alone or in combination with the twenty-seventh through twenty-ninth aspects, the second clock signal is provided to the first mixer as a first radio frequency (RF) input, wherein the clock signal is provided to the second mixer as a second RF input, and wherein during the RSB calibration operation: the first mixer of the first chain receives a first LO signal from a third oscillator of the first chain and outputs a first mixed signal based on the first LO signal and first RF input; and the second mixer of the second chain receives a second LO signal from a fourth oscillator of the second chain and outputs a second mixed signal based on the second LO signal and the second RF input.

Those of skill in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Components, the functional blocks, and the modules described herein with respect to FIGS. 1-13 include processors, electronics devices, hardware devices, electronics components, logical circuits, memories, software codes, firmware codes, among other examples, or any combination thereof. Software shall be construed broadly to mean instructions, instruction sets, code, code segments, program code, programs, subprograms, software modules, application, software applications, software packages, routines, subroutines, objects, executables, threads of execution, procedures, and/or functions, among other examples, whether referred to as software, firmware, middleware, microcode, hardware description language or otherwise. In addition, features discussed herein may be implemented via specialized processor circuitry, via executable instructions, or combinations thereof.

Those of skill in the art that one or more blocks (or operations) described with reference to FIGS. 3 and 4 may be combined with one or more blocks (or operations) described with reference to another of the figures. For example, one or more blocks (or operations) of FIG. 3 may be combined with one or more blocks (or operations) of FIG. 1. As another example, one or more blocks associated with FIG. 4 may be combined with one or more blocks (or operations) associated with FIG. 1. Additionally, or alternatively, one or more operations described above with reference to FIGS. 1-4 may be combined with one or more operations described with reference to FIGS. 5-13

Those of skill in the art would further appreciate that the various illustrative logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure. Skilled artisans will also readily recognize that the order or combination of components, methods, or interactions that are described herein are merely examples and that the components, methods, or interactions of the various aspects of the present disclosure may be combined or performed in ways other than those illustrated and described herein.

The various illustrative logics, logical blocks, modules, circuits and algorithm processes described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and processes described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, or, any conventional processor, controller, microcontroller, or state machine. In some implementations, a processor may be implemented as a combination of computing devices, such as a combination of a DSP and a microprocessor, a plurality of microprocessors, one or more microprocessors in conjunction with a DSP core, or any other such configuration. In some implementations, particular processes and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also may be implemented as one or more computer programs, which is one or more modules of computer program instructions, encoded on a computer storage media for execution by, or to control the operation of, data processing apparatus.

If implemented in software, the functions may be stored on or transmitted over as one or more instructions or code on a computer-readable medium. The processes of a method or algorithm disclosed herein may be implemented in a processor-executable software module which may reside on a computer-readable medium. Computer-readable media includes both computer storage media and communication media including any medium that may be enabled to transfer a computer program from one place to another. A storage media may be any available media that may be accessed by a computer. By way of example, and not limitation, such computer-readable media may include random-access memory (RAM), read-only memory (ROM), electrically erasable programmable read-only memory (EEPROM), CD-ROM or other optical disk storage, magnetic disk storage or other magnetic storage devices, or any other medium that may be used to store desired program code in the form of instructions or data structures and that may be accessed by a computer. Also, any connection may be properly termed a computer-readable medium. Disk and disc, as used herein, includes compact disc (CD), laser disc, optical disc, digital versatile disc (DVD), floppy disk, and Blu-ray disc where disks usually reproduce data magnetically, while discs reproduce data optically with lasers. Combinations of the above should also be included within the scope of computer-readable media. Additionally, the operations of a method or algorithm may reside as one or any combination or set of codes and instructions on a machine readable medium and computer-readable medium, which may be incorporated into a computer program product.

Various modifications to the implementations described in this disclosure may be readily apparent to those skilled in the art, and the generic principles defined herein may be applied to some other implementations without departing from the spirit or scope of this disclosure. Thus, the claims are not intended to be limited to the implementations shown herein, but are to be accorded the widest scope consistent with this disclosure, the principles and the novel features disclosed herein.

Additionally, a person having ordinary skill in the art will readily appreciate, opposing terms such as “upper” and “lower” or “front” and back” or “top” and “bottom” or “forward” and “backward” are sometimes used for ease of describing the figures, and indicate relative positions corresponding to the orientation of the figure on a properly oriented page, and may not reflect the proper orientation of any device as implemented.

Certain features that are described in this specification in the context of separate implementations also may be implemented in combination in a single implementation. Conversely, various features that are described in the context of a single implementation also may be implemented in multiple implementations separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one or more example processes in the form of a flow diagram. However, other operations that are not depicted may be incorporated in the example processes that are schematically illustrated. For example, one or more additional operations may be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems may generally be integrated together in a single software product or packaged into multiple software products. Additionally, some other implementations are within the scope of the following claims. In some cases, the actions recited in the claims may be performed in a different order and still achieve desirable results.

As used herein, including in the claims, the term “or,” when used in a list of two or more items, means that any one of the listed items may be employed by itself, or any combination of two or more of the listed items may be employed. For example, if a composition is described as containing components A, B, or C, the composition may contain A alone; B alone; C alone; A and B in combination; A and C in combination; B and C in combination; or A, B, and C in combination. Also, as used herein, including in the claims, “or” as used in a list of items prefaced by “at least one of” indicates a disjunctive list such that, for example, a list of “at least one of A, B, or C” means A or B or C or AB or AC or BC or ABC (that is A and B and C) or any of these in any combination thereof. The term “substantially” is defined as largely but not necessarily wholly what is specified (and includes what is specified; for example, substantially 90 degrees includes 90 degrees and substantially parallel includes parallel), as understood by a person of ordinary skill in the art. In any disclosed implementations, the term “substantially” may be substituted with “within [a percentage] of” what is specified, where the percentage includes 0.1, 1, 5, or 10 percent.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

What is claimed is:

1. A transceiver system, comprising:
one or more receive chains; and
one or more transmit chains,
wherein a receive chain of the one or more receive chains or a transmit chain of the one or more transmit chains includes:
one or more dividers configured to receive a clock signal;
local oscillator (LO) cross routing circuitry coupled to the one or more dividers;
a mixer coupled to the LO cross routing circuitry; and
one or more auxiliary mixers coupled to the LO cross routing circuitry, wherein the LO cross routing circuitry is configured to selectively couple a particular divider of the one or more dividers to the mixer, to at least one auxiliary mixer of the one or more auxiliary mixers, or any combination thereof.

2. The transceiver system of claim 1, wherein:
the LO cross routing circuitry comprises one or more traces and optionally one or more switches; and
the LO cross routing circuitry provides a plurality of selectable paths from the particular divider for providing the clock signal to the mixer, the least one auxiliary mixer, or both.

3. The transceiver system of claim 1, wherein the receive chain or the transmit chain includes:
a harmonic rejection mixer including the mixer and at least one auxiliary mixer of the one or more auxiliary mixers.

4. The transceiver system of claim 1, wherein:
at least one auxiliary mixer of the one or more auxiliary mixers is smaller in area than the mixer.

5. The transceiver system of claim 1, wherein:
the one or more dividers include a primary divider and an auxiliary divider; and
the LO cross routing circuitry is further configured to selectively couple the primary divider of the one or more dividers to the mixer and to at least one auxiliary mixer of the one or more auxiliary mixers.

6. The transceiver system of claim 5, wherein the primary divider has a fixed divide ratio or a configurable divide ratio, and the auxiliary divider has a configurable divide ratio.

7. The transceiver system of claim 5, wherein the LO cross routing circuitry is further configured to selectively couple the auxiliary divider of the one or more dividers to the mixer and to at least one auxiliary mixer of the one or more auxiliary mixers.

8. The transceiver system of claim 5, further comprising:
a first oscillator coupled to the one or more dividers and configured to generate the clock signal; and
a second oscillator coupled to the one or more dividers, wherein the first oscillator corresponds to a primary or high power mode oscillator, wherein the first second oscillator corresponds to a secondary or low power mode oscillator, and wherein the second oscillator has second type different from a first type of the first oscillator.

9. The transceiver system of claim 1, wherein the mixer is a primary mixer and the one or more auxiliary mixers include two or more auxiliary mixers, and further comprising:
a second primary mixer, wherein the two or more auxiliary mixers are each smaller in area than the primary mixers, consume less power, or both.

10. The transceiver system of claim 1, further comprising:
an oscillator coupled to the one or more dividers and configured to generate the clock signal, wherein the oscillator comprises a phase-locked loop (PLL), a voltage-controlled oscillator (VCO), a ring-VCO (RVCO), or an inductance-capacitance VCO (LCVCO).

11. The transceiver system of claim 1, wherein the one or more dividers include a primary divider and an auxiliary divider, wherein the LO cross routing circuitry is coupled to the primary divider and the auxiliary divider, and further comprising:
a primary mixer buffer coupled to the LO cross routing circuitry and to the mixer; and
one or more auxiliary mixer buffers coupled to the LO cross routing circuitry and to a respective auxiliary mixer of the one or more auxiliary mixers, wherein the LO cross routing circuitry is configurable to provide signals from the primary divider to the mixer via the primary mixer buffer or to at least one auxiliary mixer of the one or more auxiliary mixers via a corresponding auxiliary mixer buffer of the one or more auxiliary mixer buffers.

12. The transceiver system of claim 1, wherein the one or more dividers includes a single, shared divider, and further comprising:
a delay-locked loop (DLL) coupled to the single, shared divider and coupled to the one or more auxiliary mixers via at least one or more auxiliary mixer buffers and coupled to the mixer via at least a mixer buffer.

13. The transceiver system of claim 12, wherein the one or more auxiliary mixer buffers comprises a shared auxiliary mixer buffer for two or more auxiliary paths.

14. The transceiver system of claim 13, wherein the shared auxiliary mixer buffer includes a shared not-and (NAND) gate for multiple auxiliary paths of the two or more auxiliary paths and a buffer for each path of the multiple auxiliary paths.

15. The transceiver system of claim 1, wherein the LO cross routing circuitry is coupled to the particular divider via a buffer and comprises a plurality of traces and a plurality of switches, and wherein the plurality of traces and the plurality of switches are configured to selectively provide an output of the buffer to two primary paths or to two auxiliary paths.

16. The transceiver system of claim 1, wherein the LO cross routing circuitry is configured to selectively couple the particular divider of the one or more dividers to the mixer via corresponding mixer buffer and to at least one auxiliary mixer of the one or more auxiliary mixers via a corresponding auxiliary mixer buffer, and wherein the mixer buffer comprises a two-stage mixer buffer or a single-tone generator buffer.

17. The transceiver system of claim 1, wherein the LO cross routing circuitry is configured to selectively couple the particular divider of the one or more dividers to the mixer via corresponding mixer buffer and to at least one auxiliary mixer of the one or more auxiliary mixers via a corresponding auxiliary mixer buffer, and wherein the mixer buffer comprises a not-and (NAND) gate and a buffer.

18. A method for wireless communication, comprising:
receiving, at local oscillator (LO) cross routing circuitry, a clock signal from a divider;
selectively providing, by the LO cross routing circuitry, the clock signal to one or more of a primary mixer buffer, an auxiliary mixer buffer, or both, wherein the LO cross routing circuitry is configured to selectively couple the divider to the primary mixer buffer, the auxiliary mixer buffer, or both; and
processing, by the primary mixer buffer, the auxiliary mixer buffer, or both, the clock signal and providing the processed clock signal to a corresponding mixer.

19. The method of claim 18, wherein during a low power mode or low performance mode operation:
the LO cross routing circuitry selectively provides the clock signal from the divider to the auxiliary mixer buffer; and
the auxiliary mixer buffer processes the clock signal provides the processed clock signal to a first auxiliary mixer, and further comprising:
receiving, at the first auxiliary mixer, the processed clock signal and an RF input from an antenna; and
outputting, by the first auxiliary mixer, a mixed signal based on the processed clock signal and the RF input.

20. The method of claim 18, wherein the divider is a primary divider, and wherein during a low power mode or low performance mode operation the LO cross routing circuitry selectively provides the clock signal from the divider to auxiliary mixer buffer, and further comprising:
powering off an auxiliary divider associated with the primary divider.

21. A transceiver system, comprising:
a first oscillator;
a second oscillator;
local oscillator (LO) cross routing circuitry coupled to the first and second oscillators;
a first mixer coupled to the LO cross routing circuitry; and
a second mixer coupled to the LO cross routing circuitry,
wherein the LO cross routing circuitry is configured to selectively couple at least one of the first oscillator or the second oscillator to the first mixer or to the second mixer via a corresponding auxiliary mixer buffer, and
wherein the first oscillator and the first mixer are part of a first transmit or receive chain and the second oscillator and the second mixer are part of a second transmit or receive chain.

22. The transceiver system of claim 21, wherein:
the LO cross routing circuitry comprises one or more traces and optionally one or more switches, and
the first oscillator and the second oscillator each comprise a first type of oscillator for a low power mode, and further comprising:
third and fourth oscillators, where the third oscillator and the fourth oscillator each comprise a second type of oscillator for a high power mode;
first and second dividers, the first divider coupled to the third oscillator, the second divider coupled to the fourth oscillator,
first and second main mixer buffers, the first main mixer buffer coupled to the first divider and the first mixer, the second main mixer buffer coupled to the second divider and the second mixer; and
first and second auxiliary mixer buffers, the first auxiliary mixer buffer coupled to the LO cross routing circuitry and the first mixer, the second auxiliary mixer buffer coupled to the LO cross routing circuitry and the second mixer,
where the LO cross routing circuitry is configured to selectively couple the first oscillator to the first mixer via the first main mixer buffer or the first auxiliary mixer buffer, and
where the third oscillator and the first divider are part of the first transmit or receive chain and the fourth oscillator and the second divider are part of the second transmit or receive chain.

23. The transceiver system of claim 22, wherein the first and third oscillators are included in first phase-locked loop (PLL) circuitry, and wherein the second and fourth oscillators are included in second PLL circuitry.

24. The transceiver system of claim 23, wherein the first and second oscillators each comprise a ring voltage-controlled oscillator (RVCO), and wherein the third and fourth oscillators each comprise a voltage-controlled oscillator (VCO).

25. The transceiver system of claim 21, further comprising:
an antenna, and
a low noise amplifier coupled to the antenna and the mixers; or
a power amplifier coupled to the antenna and the mixers.

26. The transceiver system of claim 21, wherein:
the first mixer and the second mixer each comprise auxiliary mixers,
the LO cross routing circuitry comprises one or more traces and optionally one or more switches, and
the first oscillator and the second oscillator each comprise a first type of oscillator for a low power mode, and further comprising:
third and fourth oscillators, where the third oscillator and the fourth oscillator each comprise a second type of oscillator for a high power mode;
first and second dividers, the first divider coupled to the third oscillator, the second divider coupled to the fourth oscillator;
first and second main mixer buffers, the first main mixer buffer coupled to the LO cross routing circuitry, the first divider, and a first main mixer, the second main mixer buffer coupled to the LO cross routing circuitry, the second divider, and a second main mixer; and
first and second auxiliary mixer buffers, the first auxiliary mixer buffer coupled to the LO cross routing circuitry and the first auxiliary mixer, the second auxiliary mixer buffer coupled to the LO cross routing circuitry and the second auxiliary mixer, and
where the LO cross routing circuitry is configured to selectively couple the first oscillator to the first mixer via the first main mixer buffer, to the first auxiliary mixer via the first auxiliary mixer buffer, or to the second auxiliary mixer via the second auxiliary mixer buffer.

27. A method for wireless communication, comprising:
receiving, at local oscillator (LO) cross routing circuitry, a clock signal from an oscillator;
selectively providing, by the LO cross routing circuitry, the clock signal to one or more of a primary mixer buffer of a first chain, a first auxiliary mixer buffer of the first chain, a second auxiliary mixer buffer of a second chain, or a combination thereof, wherein the LO cross routing circuitry is configured to selectively couple the oscillator to mixers of multiple chains; and
processing, by the primary mixer buffer, the first auxiliary mixer buffer, the second auxiliary mixer buffer of a second chain, or a combination thereof, the clock signal and providing the clock signal to a corresponding mixer of the mixers.

28. The method of claim 27, further comprising:
receiving, at the LO cross routing circuitry from a second oscillator, a second clock signal;
selectively providing, by the LO cross routing circuitry, the second clock signal to one or more of a second primary mixer buffer of the second chain, the first auxiliary mixer buffer of the first chain, the second auxiliary mixer buffer of the second chain, or a combination thereof, wherein the LO cross routing circuitry is configured to selectively couple the second oscillator to mixers of multiple chains; and
processing, by the second primary mixer buffer, the first auxiliary mixer buffer, the second auxiliary mixer buffer, or a combination thereof, the second clock signal and providing the second clock signal to a corresponding mixer.

29. The method of claim 28, wherein during a residual sideband (RSB) calibration operation:
the LO cross routing circuitry selectively provides:
the clock signal from the oscillator of the first chain to the second auxiliary mixer buffer of the second chain; and
the second clock signal from the second oscillator of the second chain to the first auxiliary mixer buffer of the first chain;
the first auxiliary mixer buffer provides the second clock signal to a first mixer of the first chain; and
the second auxiliary mixer buffer provides the clock signal to a second mixer of the second chain.

30. The method of claim 29, wherein the second clock signal is provided to the first mixer as a first radio frequency (RF) input, wherein the clock signal is provided to the second mixer as a second RF input, and wherein during the RSB calibration operation:
the first mixer of the first chain receives a first LO signal from a third oscillator of the first chain and outputs a first mixed signal based on the first LO signal and first RF input; and
the second mixer of the second chain receives a second LO signal from a fourth oscillator of the second chain and outputs a second mixed signal based on the second LO signal and the second RF input.
